(19) United States
(12) Patent Application Publication
(10) Pub. No.: US 2025/0261510 A1
(43) Pub. Date: Aug. 14, 2025

(54) SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Yukinori SHIMA, Tatebayashi (JP); Masakatsu OHNO, Utsunomiya (JP); Junichi KOEZUKA, Tochigi (JP)

(21) Appl. No.: 18/864,123

(22) PCT Filed: May 12, 2023
(86) PCT No.: PCT/IB2023/054909

§ 371 Date: Nov. 8, 2024

(30) Foreign Application Priority Data
May 27, 2022 (JP) 2022-086818

(51) Int. Cl. H10K 59/121; H10K 59/124

(52) U.S. Cl. CPC H10K 59/1213; H10K 59/124

(57) ABSTRACT

A semiconductor device that has both low power consumption and high performance is provided. The semiconductor device includes a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. A conductivity of the first semiconductor layer is higher than a conductivity of the second semiconductor layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method of driving any of them, and a manufacturing method of any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### BACKGROUND ART

Semiconductor devices that include transistors are applied to a wide range of electronic devices. In a display device, for example, when the area occupied by transistors is reduced, the pixel size can be reduced and resolution can be increased. Thus, minute transistors have been required.

As devices requiring high-resolution display devices, for example, devices for virtual reality (VR), augmented reality (AR), substitutional reality (SR), or mixed reality (MR) have been actively developed.

As a display device, a light-emitting apparatus including an organic EL (Electro Luminescence) element or a light-emitting diode (LED) has been developed.

Patent Document 1 discloses a high-resolution display device using an organic EL element.

### REFERENCE

### Patent Document

[Patent Document 1] PCT International Publication No. 2016/038508

### SUMMARY OF THE INVENTION

### Problems to be Solved by the Invention

One object of one embodiment of the present invention is to provide a transistor having a minute size. Another object is to provide a transistor having a short channel length. Another object is to provide a transistor having high on-state current. Another object is to provide a transistor having low cutoff current. Another object is to provide a transistor having favorable electric characteristics. Another object is to provide a semiconductor device that occupies a small area. Another object is to provide a semiconductor device having small wiring resistance. Another object is to provide a semiconductor device or a display device having low power consumption. Another object is to provide a transistor, a semiconductor device, or a display device having high reliability. Another object is to provide a high-resolution display device. Another object is to provide a method for manufacturing a semiconductor device or a display device having high productivity. Another object is to provide a novel transistor, a novel semiconductor device, a novel display device, and manufacturing methods thereof.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. A conductivity of the first semiconductor layer is different from a conductivity of the second semiconductor layer.

One embodiment of the present invention is a semiconductor device including a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. A conductivity of the first semiconductor layer is higher than a conductivity of the second semiconductor layer.

One embodiment of the present invention is a semiconductor device including a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. The first semiconductor layer includes a first metal oxide. The second semiconductor layer includes a second metal oxide. A band gap of the first metal oxide is smaller than a band gap of the second metal oxide.

One embodiment of the present invention is a semiconductor device including a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. The first semiconductor layer includes a first metal oxide. The second semiconductor layer includes a second metal oxide. The first metal oxide includes indium. The second metal oxide includes indium and an element M. The element M is one or more of gallium, aluminum, and tin. A content percentage of the element M in the first metal oxide is lower than a content percentage of the element M in the second metal oxide.

One embodiment of the present invention is a semiconductor device including a first semiconductor layer, a second semiconductor layer, a first conductive layer, a second conductive layer, a third conductive layer, a first insulating layer, and a second insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The second insulating layer is provided over the second semiconductor layer. The third conductive layer is provided over the second insulating layer. The first semiconductor layer and the second semiconductor layer each include a metal oxide. A crystallinity of the first semiconductor layer is lower than a crystallinity of the second semiconductor layer.

In the above semiconductor device, the first conductive layer and the second conductive layer each include an oxide conductor.

In the above semiconductor device, the first insulating layer preferably includes a third insulating layer, a fourth insulating layer over the third insulating layer, and a fifth insulating layer over the fourth insulating layer. The fourth insulating layer preferably includes oxygen. The third insulating layer and the fifth insulating layer each preferably include nitrogen.

In the above semiconductor device, the first insulating layer preferably includes a third insulating layer, a fourth insulating layer over the third insulating layer, a fifth insulating layer over the fourth insulating layer, and a sixth insulating layer over the fifth insulating layer. The fifth insulating layer preferably includes oxygen. The third insulating layer, the fourth insulating layer, and the sixth insulating layer each preferably include nitrogen. The third insulating layer preferably includes a region having a higher hydrogen content than the fourth insulating layer.

The above semiconductor device preferably includes a fourth insulating layer. The fourth conductive layer preferably includes a region in contact with the top surface of the first conductive layer. The first insulating layer preferably includes a region in contact with the top surface of the first conductive layer and a top surface and a side surface of the fourth conductive layer. The fourth conductive layer preferably includes a region overlapping with the third conductive layer with the first insulating layer, the first semiconductor layer, the second semiconductor layer, and the second insulating layer therebetween. A conductivity of the fourth conductive layer is higher than a conductivity of the first conductive layer.

### Effect of the Invention

One embodiment of the present invention can provide a transistor having a minute size. Alternatively, a transistor having a short channel length can be provided. Alternatively, a transistor having high on-state current can be provided. Alternatively, a transistor having low cutoff current can be provided. Alternatively, a transistor having favorable electrical characteristics can be provided. Alternatively, a semiconductor device that occupies a small area can be provided. Alternatively, a semiconductor device having small wiring resistance can be provided. Alternatively, a semiconductor device or a display device having low power consumption can be provided. Alternatively, a transistor, a semiconductor device, or a display device having high reliability can be provided. Alternatively, a high-resolution display device can be provided. Alternatively, a method for manufacturing a semiconductor device or a display device having high productivity can be provided. A novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating examples of the semiconductor device.

FIG. 2A to FIG. 2D are perspective views illustrating examples of a semiconductor device.

FIG. 3A is a top view illustrating an example of a semiconductor device. FIG. 3B is a cross-sectional view illustrating an example of a semiconductor device.

FIG. 4A to FIG. 4C are cross-sectional views illustrating examples of a semiconductor device.

FIG. 5A and FIG. 5B are cross-sectional views illustrating examples of a semiconductor device.

FIG. 6A and FIG. 6B are cross-sectional views illustrating examples of a semiconductor device.

FIG. 7A and FIG. 7B are cross-sectional views illustrating examples of a semiconductor device.

FIG. 8A and FIG. 8B are cross-sectional views illustrating examples of a semiconductor device.

FIG. 9 is a cross-sectional view illustrating an example of a semiconductor device.

FIG. 10A is a top view illustrating an example of a semiconductor device. FIG. 10B is a cross-sectional view illustrating an example of the semiconductor device.

FIG. 11A and FIG. 11B are cross-sectional views illustrating examples of a semiconductor device.

FIG. 12A to FIG. 12D are cross-sectional views illustrating an example of a method for manufacturing a semiconductor device.

FIG. 13A to FIG. 13C are cross-sectional views illustrating an example of a method for manufacturing a semiconductor device.

FIG. 14A to FIG. 14C are cross-sectional views illustrating an example of a method for manufacturing a semiconductor device.

FIG. 15A and FIG. 15B are cross-sectional views illustrating an example of a method for manufacturing a semiconductor device.

FIG. 16 is a perspective view illustrating an example of a display device.

FIG. 17 is a cross-sectional view illustrating an example of a display device.

FIG. 18 is a cross-sectional view illustrating an example of a display device.

FIG. 19 is a cross-sectional view illustrating an example of a display device.

FIG. 20A to FIG. 20C are cross-sectional views illustrating examples of a display device.

FIG. 21 is a cross-sectional view illustrating an example of a display device.

FIG. 22 is a cross-sectional view illustrating an example of a display device.

FIG. 23 is a cross-sectional view illustrating an example of a display device.

FIG. 24A to FIG. 24F are cross-sectional views illustrating an example of a method for manufacturing a display device.

FIG. 25A to FIG. 25D are diagrams illustrating examples of electronic devices.

FIG. 26A to FIG. 26F are diagrams illustrating examples of electronic devices.

FIG. 27A to FIG. 27G are diagrams illustrating examples of electronic devices.

FIG. 28A and FIG. 28B are diagrams each showing I_{d}-V_{g} characteristics of transistors.

FIG. 29A and FIG. 29B are diagrams each showing I_{d}-V_{g} characteristics of transistors.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Thus, the terms “source” and “drain” can be switched in this specification and the like.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Unless otherwise specified, off-state current in this specification and the like refers to leakage current between a source and a drain of a transistor in an off state (also referred to as a non-conduction state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the structure are not necessarily completely flat and may be substantially flat with a slight curvature or substantially flat with slight unevenness.

In this specification and the like, a device formed using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

Note that in this specification and the like, a sacrificial layer (also referred to as a mask layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is split because of the shape of the formation surface (e.g., a step).

### Embodiment 1

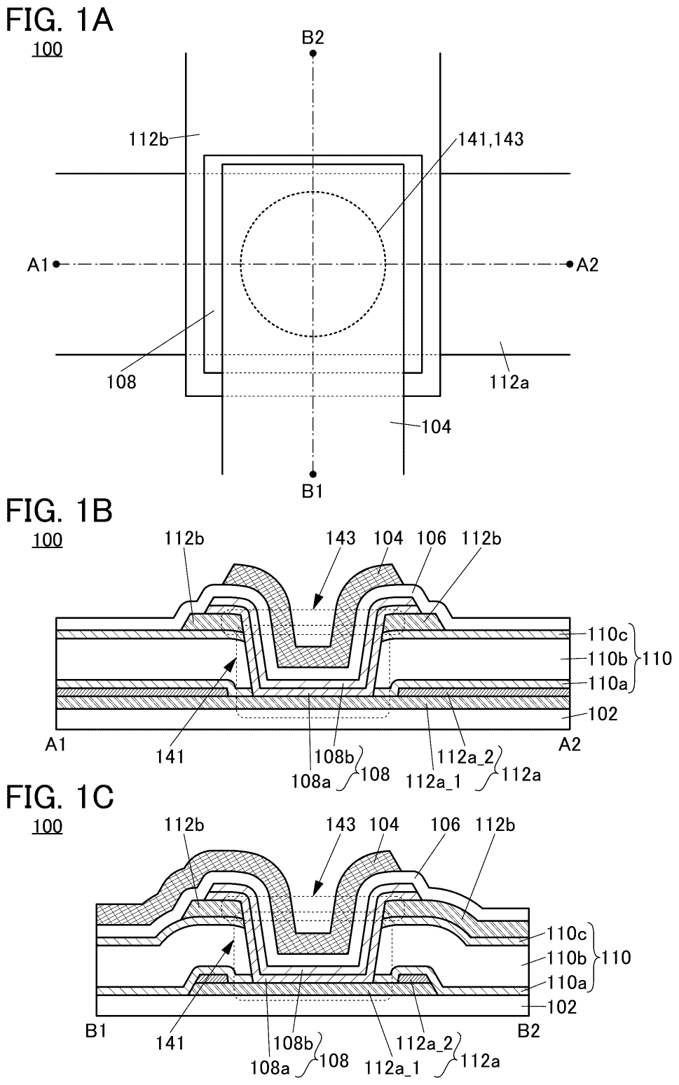

In this embodiment, a semiconductor device of one embodiment of the present invention is described with reference to FIG. 1 to FIG. 11.

### Structure Example 1

Transistors that can be used in the semiconductor device of one embodiment of the present invention are described. FIG. 1A illustrates a top view of a transistor 100. FIG. 1B is a cross-sectional view of a cut plane along the dashed-dotted line A1-A2 in FIG. 1A, and FIG. 1C is a cross-sectional view of a cut plane along the dashed-dotted line B1-B2. Note that in FIG. 1A, some components (e.g., a gate insulating layer) of the transistor 100 are not illustrated. Some components are not illustrated in top views of transistors in the following drawings, as in FIG. 1A.

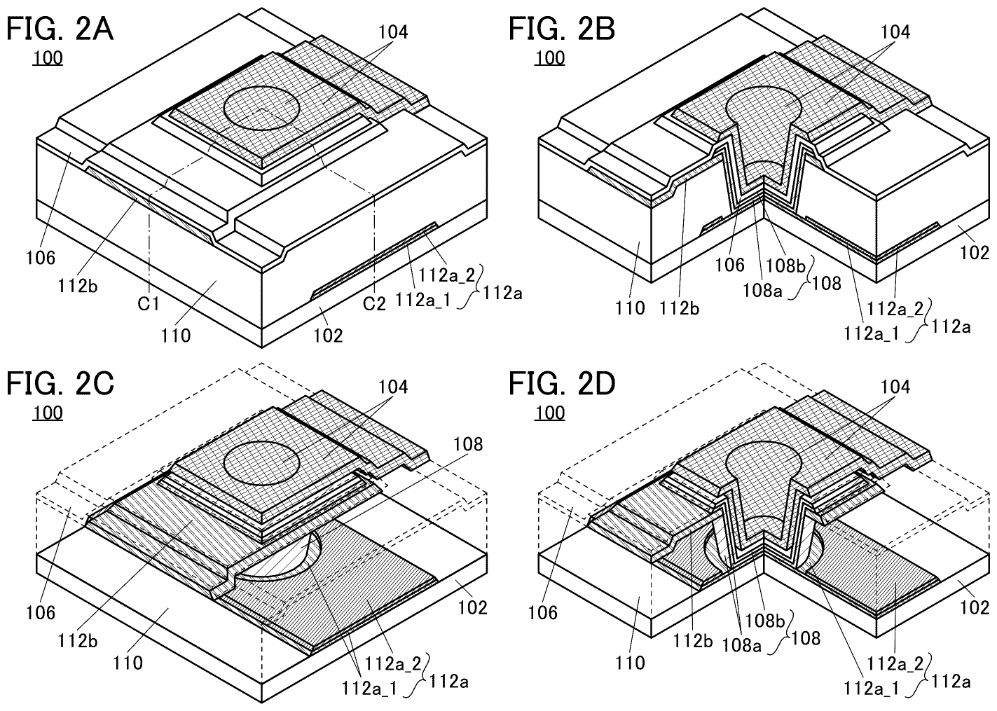

FIG. 2A to FIG. 2D illustrate perspective views of the transistor 100. Note that FIG. 2B illustrates a cut plane along the dashed-dotted line C1-C2 in FIG. 2A. In FIG. 2C, the insulating layer illustrated in FIG. 2A is transparent and its outline is indicated by a dashed line. Similarly, in FIG. 2D, the insulating layer illustrated in FIG. 2B is transparent and its outline is indicated by a dashed line.

The transistor 100 is provided over a substrate 102. The transistor 100 includes a conductive layer 104, an insulating layer 106, a semiconductor layer 108, a conductive layer 112a, and a conductive layer 112b. The conductive layer 104 functions as a gate electrode (that can also be referred to as a first gate electrode). Part of the insulating layer 106 functions as a gate insulating layer (that can also be referred to as a first gate insulating layer). The conductive layer 112a functions as one of a source electrode and a drain electrode, and the conductive layer 112b functions as the other. In the semiconductor layer 108 between the source electrode and the drain electrode, the whole region overlapping with the gate electrode with the gate insulating layer therebetween functions as a channel formation region. In the semiconductor layer 108, a region in contact with the source electrode functions as a source region, and a region in contact with the drain electrode functions as a drain region.

The conductive layer 112a is provided over the substrate 102, an insulating layer 110 is provided over the conductive layer 112a, and the conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. The insulating layer 110 has an opening 141 reaching the conductive layer 112a. It can be said that the conductive layer 112a is exposed in the opening 141. The conductive layer 112b has an opening 143 in a region overlapping with the conductive layer 112a. The opening 143 is provided in a region overlapping with the opening 141.

The semiconductor layer 108 is provided to cover the opening 141 and the opening 143. The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a.

The insulating layer 106 functioning as the gate insulating layer of the transistor 100 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface of the insulating layer 110, the top surface and the side surface of the conductive layer 112b, the top surface and the side surface of the semiconductor layer 108, and the top surface of the conductive layer 112a.

The conductive layer 104 functioning as the gate electrode of the transistor 100 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and drain current flows in a direction perpendicular or substantially perpendicular to the surface of the substrate 102. In the transistor 100, drain current can also be regarded as flowing in the vertical direction or the substantially vertical direction. Accordingly, the transistor of one embodiment of the present invention can be referred to as a vertical-channel transistor or a vertical field-effect transistor (VFET).

The channel length of the transistor 100 can be controlled by the thickness of the insulating layer 110 provided between the conductive layer 112a and the conductive layer 112b. Accordingly, a transistor with a channel length smaller than the resolution limit of a light exposure apparatus used for manufacturing the transistor can be manufactured with high accuracy. Furthermore, variations in characteristics among the transistors 100 are also reduced. Accordingly, the operation of the semiconductor device including the transistor 100 can be stabilized and the reliability thereof can be improved. When the variations in characteristics is reduced, the circuit design flexibility is increased and the operation voltage of the semiconductor device can be reduced. Thus, the power consumption of the semiconductor device can be reduced.

In the transistor of one embodiment of the present invention, since the source electrode, the semiconductor layer, and the drain electrode can be provided to overlap with each other, the area occupied by the transistor can be significantly reduced as compared with a so-called planar transistor in which a semiconductor layer is positioned over a flat surface.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel.

Although the semiconductor layer 108, the insulating layer 106, and the conductive layer 104 cover the opening 141 and the opening 143 in FIG. 1A, for example, one embodiment of the present invention is not limited thereto. A step may be formed between the conductive layer 112a and each of the insulating layer 110 and the conductive layer 112b, and the semiconductor layer 108, the insulating layer 106, and the conductive layer 104 may be provided along with the step.

### [Semiconductor Layer 108]

The semiconductor layer 108 preferably has a stacked-layer structure. FIG. 1B and the like illustrate a structure in which the semiconductor layer 108 has a stacked-layer structure of a semiconductor layer 108a and a semiconductor layer 108b over the semiconductor layer 108a.

The conductivity of a material used for the semiconductor layer 108a is preferably different from the conductivity of a material used for the semiconductor layer 108b.

For example, a material having higher conductivity than the semiconductor layer 108b can be used for the semiconductor layer 108a. The use of the material having high conductivity for the semiconductor layer 108a, which is in contact with the conductive layer 112a and the conductive layer 112b functioning as the source electrode and the drain electrode, can reduce the contact resistance between the semiconductor layer 108 and the conductive layer 112a and the contact resistance between the semiconductor layer 108 and the conductive layer 112b, so that the transistor can have high on-state current.

Here, in the case where a material having high conductivity is used for the semiconductor layer 108b provided on the side of the conductive layer 104 functioning as the gate electrode, the threshold voltage of the transistor is shifted and drain current flowing when the gate voltage is 0 V (hereinafter also referred to as cutoff current) becomes large in some cases. Specifically, in the case where the transistor 100 is an n-channel transistor, the threshold voltage might be low, and in the case where the transistor 100 is a p-channel transistor, the threshold voltage might be high. Thus, a material having lower conductivity than the semiconductor layer 108a is preferably used for the semiconductor layer 108b. Accordingly, the transistor 100 can have high threshold voltage in the case where the transistor is an n-channel transistor, and the transistor 100 can have low threshold voltage in the case where the transistor is a p-channel transistor; in both of the cases, the transistor 100 can have low cut-off current. Note that characteristics with low cut-off current is sometimes referred to as normally-off characteristics.

When the semiconductor layer 108 has a stacked-layer structure and a material having higher conductivity than a material for the semiconductor layer 108b is used for the semiconductor layer 108a, as described above, the transistor can have normally-off characteristics and high on-state current. Consequently, the semiconductor device can have both low power consumption and high performance.

Note that the carrier concentration of the semiconductor layer 108a is preferably higher than that of the semiconductor layer 108b. Increasing the carrier concentration of the semiconductor layer 108a results in higher conductivity thereof, which can reduce the contact resistance between the semiconductor layer 108 and the conductive layer 112a and the contact resistance between the semiconductor layer 108 and the conductive layer 112b, so that the transistor can have high on-state current. When the carrier concentration of the semiconductor layer 108b is reduced, the conductivity is reduced, so that the transistor can have normally-off characteristics.

Although an example in which a material having higher conductivity than the semiconductor layer 108b is used for the semiconductor layer 108a is described here, one embodiment of the present invention is not limited thereto. A material having lower conductivity than the semiconductor layer 108b may be used for the semiconductor layer 108a. The carrier concentration of the semiconductor layer 108a can be lower than that of the semiconductor layer 108b.

A semiconductor material that can be used for each of the semiconductor layer 108a and the semiconductor layer 108b is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may include an impurity as a dopant.

There is no particular limitation on the crystallinity of a semiconductor material used for each of the semiconductor layer 108a and the semiconductor layer 108b, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The semiconductor layer 108a and the semiconductor layer 108b each preferably includes a metal oxide (also referred to as an oxide semiconductor) exhibiting semiconductor characteristics.

The band gap of a first metal oxide used for the semiconductor layer 108a and the band gap of a second metal oxide used for the semiconductor layer 108b are each preferably 2.0 eV or more, further preferably 2.5 eV or more.

The band gap of the first metal oxide used for the semiconductor layer 108a and the band gap of the second metal oxide used for the semiconductor layer 108b are preferably different from each other. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the semiconductor layer 108a can be smaller than the band gap of the second metal oxide used for the semiconductor layer 108b. Thus, the contact resistance between the semiconductor layer 108 and the conductive layer 112a and the contact resistance between the semiconductor layer 108 and the conductive layer 112b can be reduced, so that the transistor can have high on-state current. Furthermore, the transistor 100 can have high threshold voltage in the case where the transistor is an n-channel transistor, and the transistor 100 can have low threshold voltage in the case where the transistor is a p-channel transistor; in both of the cases, the transistor 100 can be a normally-off transistor.

Although an example in which the band gap of the first metal oxide is smaller than that of the second metal oxide is described here, one embodiment of the present invention is not limited thereto. The band gap of the first metal oxide can be larger than that of the second metal oxide.

Examples of the first metal oxide and the second metal oxide include indium oxide, gallium oxide, and zinc oxide. The metal oxide preferably includes at least indium or zinc. The metal oxide preferably includes two or three kinds selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, for each of the first metal oxide and the second metal oxide, an indium zinc oxide (also referred to as In—Zn oxide or IZO (registered trademark)), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, an indium tin oxide including silicon, gallium tin oxide (Ga—Sn oxide), an aluminum tin oxide (Al—Sn oxide), or the like can be used.

When the proportion of the number of indium atoms in the total number of atoms of all the metal elements included in the metal oxide is increased, the field-effect mobility of the transistor can be increased. In addition, the transistor can have high on-state current.

Note that the metal oxide may include, instead of or in addition to indium, one or more kinds of metal elements belonging to a period of a higher number in the periodic table. The larger the overlap between orbits of metal elements is, the more likely it is that the metal oxide will have high carrier conductivity. Thus, a transistor including a metal element belonging to a period of a higher number in the periodic table can have high field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds selected from nonmetallic elements. By including a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited and the reliability of the transistor can be improved.

Electrical characteristics and reliability of a transistor depend on the composition of the metal oxide used for the semiconductor layer 108a and the semiconductor layer 108b. Thus, by varying the composition of the metal oxide in accordance with the electrical characteristics and reliability required for the transistor, the semiconductor device can have both good electrical characteristics and high reliability.

When a metal oxide is an In-M-Zn oxide, the atomic ratio of In is preferably higher than or equal to the atomic ratio of the element M in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 or a composition in the neighborhood thereof. Note that a composition in the neighborhood includes the range of ±30% of an intended atomic ratio. By increasing the atomic ratio of indium in the metal oxide, the on-state current and field-effect mobility of the transistor can be increased.

The atomic ratio of In may be less than the atomic ratio of the element M in the In-M-Zn oxide. Examples of the atomic ratio of the metal elements in such an In-M-Zn oxide include In:M:Zn=1:3:2, In:M:Zn=1:3:3, In:M:Zn=1:3:4 or a composition in the neighborhood thereof. By increasing the atomic ratio of the element M in the metal oxide, generation of oxygen vacancies can be inhibited.

In the case where a plurality of metal elements are included as the element M, the sum of the proportions of the numbers of atoms of the metal elements can be the proportion of the number of element M atoms.

In this specification and the like, the atomic proportion of indium with respect to the total number of atoms of all the included metal elements is sometimes referred to as indium content percentage. The same applies to other metal elements.

As described above, the band gap of the first metal oxide used for the semiconductor layer 108a can be smaller than the band gap of the second metal oxide used for the semiconductor layer 108b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or more of gallium, aluminum, and tin as the element M.

The first metal oxide may have a composition not including the element M. For example, the first metal oxide used for the semiconductor layer 108a can be an In—Zn oxide, and the second metal oxide used for the semiconductor layer 108b can be an In-M-Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof, and the second metal oxide can have an atomic ratio of In:Ga:Zn=1:1:1 or a composition in the neighborhood thereof.

Although an example in which the content percentage of the element M in the first metal oxide is lower than that of the element M in the second metal oxide is described here, one embodiment of the present invention is not limited thereto. The content percentage of the element M in the first metal oxide may be higher than that of the element M in the second metal oxide. Note that as long as the compositions of the first metal oxide and the second metal oxide are different from each other, the content percentages of elements other than the element M may be different from each other.

As an analysis method of the composition of the first metal oxide used for the semiconductor layer 108a and the composition of the second metal oxide used for the semiconductor layer 108b, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of the zinc in the formed metal oxide may be reduced to approximately 50% of that of the sputtering target.

It is preferable to use a metal oxide having crystallinity for each of the semiconductor layer 108a and the semiconductor layer 108b. Examples of the structure of a metal oxide having crystallinity include a c-axis aligned crystalline (CAAC) structure, a polycrystalline structure, and a nano-crystal (nc) structure. With use of a metal oxide having crystallinity for the semiconductor layer 108, the density of defect states in the semiconductor layer 108 can be reduced, which enables the semiconductor device to have high reliability.

When a metal oxide having high crystallinity is used for the semiconductor layer, the density of defect states in the semiconductor layer can be reduced. By contrast, the use of a metal oxide having low crystallinity enables a transistor to flow a large amount of current.

In the case where the metal oxide is formed by a sputtering method, the crystallinity of the formed metal oxide can be increased as the substrate temperature at the time of formation is higher. For example, the substrate temperature at the time of formation can be adjusted by the temperature of the stage on which the substrate is placed. The crystallinity of the formed metal oxide can be increased with a higher proportion of the flow rate of an oxygen gas to the total flow rate of the film formation gas used at the time of formation (hereinafter also referred to as a higher oxygen flow rate ratio) or with higher oxygen partial pressure in a processing chamber of a film formation apparatus.

The composition of the first metal oxide used for the semiconductor layer 108a may be the same or substantially the same as that of the second metal oxide used for the semiconductor layer 108b. Employing the metal oxides having the same composition can reduce the manufacturing cost because the metal oxide can be formed using the same sputtering target. Here, the degree of crystallinity of the semiconductor layer 108a is preferably different from the degree of crystallinity of the semiconductor layer 108b. For example, the crystallinity of the semiconductor layer 108a can be lower than that of the semiconductor layer 108b. When the crystallinity of the semiconductor layer 108a is lower than that of the semiconductor layer 108b, the conductivity of the semiconductor layer 108a can be increased. Thus, the contact resistance between the semiconductor layer 108 and the conductive layer 112a and the contact resistance between the semiconductor layer 108 and the conductive layer 112b can be reduced, so that the transistor can have high on-state current. By contrast, when the crystallinity of the semiconductor layer 108b is higher than that of the semiconductor layer 108a, the conductivity of the semiconductor layer 108b can be decreased. Accordingly, a normally-off transistor can be obtained. Furthermore, providing the semiconductor layer 108b having high crystallinity on the insulating layer 106 side can reduce damage to the semiconductor layer 108 at the time of forming the insulating layer 106. When the crystallinity of the semiconductor layer 108a is made lower than that of the semiconductor layer 108b in this manner, the transistor can have normally-off characteristics and high on-state current. Consequently, the semiconductor device can have both low power consumption and high performance.

For example, the semiconductor layer 108a can have a microcrystalline (nc) structure, and the semiconductor layer 108b can have a CAAC structure. Alternatively, the semiconductor layer 108a and the semiconductor layer 108b may each have a microcrystalline (nc) structure, and the crystallinity of the semiconductor layer 108a may be lower than that of the semiconductor layer 108b.

Although an example in which the crystallinity of the semiconductor layer 108a is lower than that of the semiconductor layer 108b is described here, one embodiment of the present invention is not limited thereto. The crystallinity of the semiconductor layer 108a may be higher than that of the semiconductor layer 108b. Increasing the crystallinity of the semiconductor layer 108a in contact with the conductive layer 112a and the conductive layer 112b can inhibit diffusion of components included in the conductive layer 112a and the conductive layer 112b into the semiconductor layer 108b provided on the side of the conductive layer 104 functioning as a gate electrode. Thus, a change in electrical characteristics of the transistor can be inhibited and the reliability of the transistor can be improved.

The crystallinity of the semiconductor layer 108a and the semiconductor layer 108b can be analyzed with X-ray diffraction (XRD), a transmission electron microscope (TEM), electron diffraction (ED), or the like, for example. Alternatively, such kinds of analysis methods may be performed in combination.

Note that in the case where the composition of the first metal oxide is the same or substantially the same as the composition of the second metal oxide, a boundary (interface) between the semiconductor layer 108a and the semiconductor layer 108b cannot be clearly observed in some cases.

The film thickness of the semiconductor layer 108 is preferably larger than or equal to 3 nm and smaller than or equal to 200 nm, further preferably larger than or equal to 3 nm and smaller than or equal to 100 nm, further preferably larger than or equal to 5 nm and smaller than or equal to 100 nm, further preferably larger than or equal to 10 nm and smaller than or equal to 100 nm, further preferably larger than or equal to 10 nm and smaller than or equal to 70 nm, further preferably larger than or equal to 15 nm and smaller than or equal to 70 nm, further preferably larger than or equal to 15 nm and smaller than or equal to 50 nm, further preferably larger than or equal to 20 nm and smaller than or equal to 50 nm.

The thicknesses of the layers included in the semiconductor layer 108 (here, the semiconductor layer 108a and the semiconductor layer 108b) are determined so that the thickness of the semiconductor layer 108 is within the above-described range. The thickness of the semiconductor layer 108a can be determined so that the contact resistance between the semiconductor layer 108 and the conductive layer 112a and the contact resistance between the semiconductor layer 108 and the conductive layer 112b are within the required range. The thickness of the semiconductor layer 108b can be determined so that the threshold voltage of the transistor are within the required range. Note that the thickness of the semiconductor layer 108a may be the same as or different from the thickness of the semiconductor layer 108b.

In the case where an oxide semiconductor is used for the semiconductor layer 108, hydrogen included in the oxide semiconductor reacts with oxygen bonded to a metal atom to be water, and thus sometimes forms oxygen vacancy (V_{O}) in the oxide semiconductor. In some cases, a defect where hydrogen enters oxygen vacancy (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that includes a large amount of hydrogen is likely to have normally-on characteristics. Moreover, hydrogen in an oxide semiconductor is easily transferred by a stress such as heat or an electric field; thus, a large amount of hydrogen included in an oxide semiconductor might reduce the reliability of a transistor.

Accordingly, in the case where an oxide semiconductor is used for the semiconductor layer 108, the amount of V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill oxygen vacancy. When an oxide semiconductor with sufficiently reduced impurities such as V_{O}H is used for a channel formation region of a transistor, the transistor can have stable electrical characteristics. Supplying oxygen to the oxide semiconductor to fill oxygen vacancy is sometimes referred to as oxygen adding treatment.

When an oxide semiconductor is used for the semiconductor layer 108, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³. In the semiconductor layer 108b provided on the side of the conductive layer 104 functioning as a gate electrode, the carrier concentration of the region functioning as the channel formation region is particularly preferably low and is preferably within the above-described range.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for along period. Furthermore, the power consumption of the semiconductor device can be reduced with the OS transistor.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

As silicon that can be used for the semiconductor layer 108, single crystal silicon, polycrystalline silicon, microcrystalline silicon, and amorphous silicon can be given. Examples of polycrystalline silicon include low-temperature polysilicon (LTPS).

The transistor including amorphous silicon in the semiconductor layer 108 can be formed over a large glass substrate, and can be manufactured at low cost. The transistor including polycrystalline silicon in the semiconductor layer 108 has high field-effect mobility and enables high-speed operation. The transistor including microcrystalline silicon in the semiconductor layer 108 has higher field-effect mobility and enables higher speed operation than the transistor including amorphous silicon.

The semiconductor layer 108 may include a layered substance that functions as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

Although FIG. 1B and the like illustrate an example in which the semiconductor layer 108 has a two-layer structure of the semiconductor layer 108a and the semiconductor layer 108b, one embodiment of the present invention is not limited thereto. The semiconductor layer 108 may have a stacked-layer structure of three or more layers. Note that the semiconductor layer 108 may have a single-layer structure.

### [Opening 141 and Opening 143]

There is no limitation on the top surface shapes of the opening 141 and the opening 143, and the shapes can be polygons such as a circle, an ellipse, a triangle, a tetragon (including a rectangle, a rhombus, and a square), and a pentagon; and polygons with rounded corners, for example. Note that the polygon may be a concave polygon (a polygon at least one of the interior angles of which is greater than 180°) or a convex polygon (a polygon all the interior angles of which are less than or equal to 180°). The top surface shapes of the opening 141 and the opening 143 are each preferably a circle as illustrated in FIG. 1A and the like. When the top surface shapes of the openings are circles, processing accuracy at the time of formation of the openings can be high, whereby the openings can be formed to have minute sizes. Note that in this specification and the like, a circular shape is not necessarily a perfect circular shape.

In this specification and the like, the top surface shape of the opening 141 refers to the shape of the end portion of the top surface of the insulating layer 110 on the opening 141 side. The top surface shape of the opening 143 refers to the shape of the end portion of the bottom surface of the conductive layer 112b on the opening 143 side.

As shown in FIG. 1A and the like, the opening 141 and the opening 143 can have the same or substantially the same top surface shapes. In that case, it is preferable that the end portion of the bottom surface of the conductive layer 112b on the opening 143 side be aligned with or substantially aligned with the end portion of the top surface of the insulating layer 110 on the opening 141 side as shown in FIG. 1B, FIG. 1C, and the like. The bottom surface of the conductive layer 112b refers to the surface thereof on the insulating layer 110 side. The top surface of the insulating layer 110 refers to the surface thereof on the conductive layer 112b side.

Note that the opening 141 and the opening 143 do not necessarily have the same top surface shapes. In the case where the opening 141 and the opening 143 have circular top surface shapes, the opening 141 and the opening 143 may be, but not necessarily, concentrically arranged.

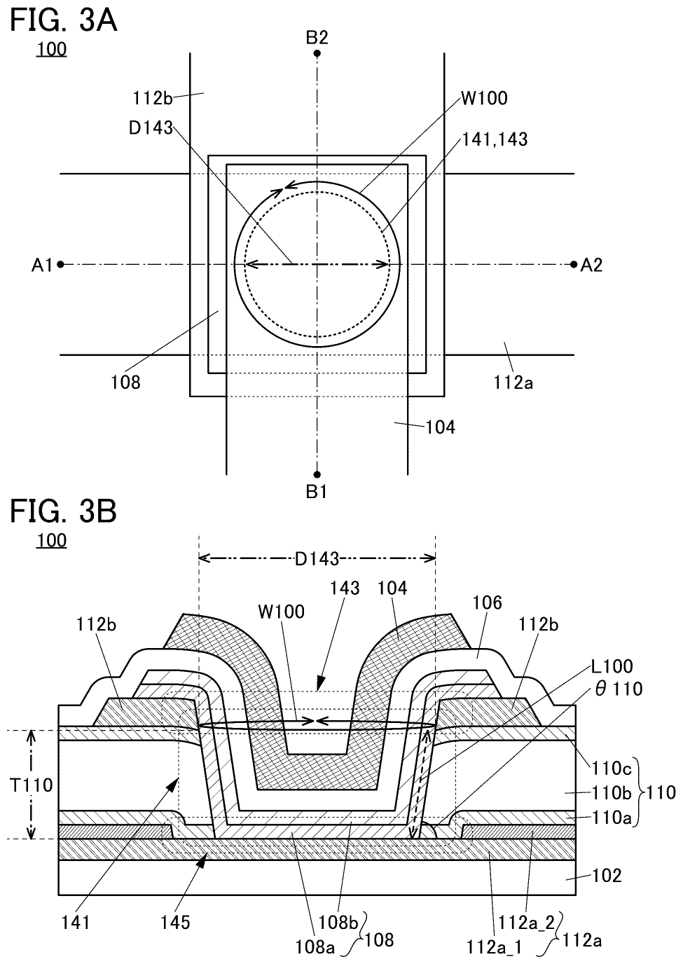

The channel length and the channel width of the transistor 100 will be described with reference to FIG. 3A and FIG. 3B.

In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is a distance between the source region and the drain region. In FIG. 3B, a channel length L100 of the transistor 100 is indicated by a dashed double-headed arrow. It can be said that in a cross-sectional view, the channel length L100 is the shortest distance between a region of the semiconductor layer 108 that is in contact with the conductive layer 112a and a region of the semiconductor layer 108 that is in contact with the conductive layer 112b.

The channel length L100 of the transistor 100 corresponds to the length of the side surface of the insulating layer 110 on the opening 141 side in a cross-sectional view. In other words, the channel length L100 depends on a thickness T110 of the insulating layer 110 and an angle θ110 formed by the side surface of the insulating layer 110 on the opening 141 side and the formation surface of the insulating layer 110 (here, the top surface of the conductive layer 112a). Thus, for example, the channel length L100 can be a value smaller than that of the resolution limit of a light-exposure apparatus, which enables a transistor having a minute size. Specifically, a transistor with an extremely short channel length that could not be achieved with a conventional light-exposure apparatus for mass production of flat panel displays (the minimum line width:approximately 2 μm or approximately 1.5 μm, for example) can be achieved. Moreover, a transistor with a channel length of less than 10 nm can also be achieved without using an extremely expensive light-exposure apparatus used in the latest LSI technology.

The channel length L100 can be, for example, greater than or equal to 5 nm, greater than or equal to 7 nm, or greater than or equal to 10 nm and less than 3 m, less than or equal to 2.5 μm, less than or equal to 2 μm, less than or equal to 1.5 μm, less than or equal to 1.2 m, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display device or a high-resolution display device can reduce signal delay in wirings and reduce display unevenness even if the number of wirings is increased, for example. In addition, since the area occupied by the circuit can be reduced, the bezel of the display device can be narrowed.

By adjusting the thickness T110 and the angle θ110 of the insulating layer 110, the channel length L100 can be controlled. In FIG. 3B, the thickness T110 of the insulating layer 110 is indicated by a dashed-dotted double-headed arrow.

The thickness T110 of the insulating layer 110 can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3 μm, less than or equal to 2.5 μm, less than or equal to 2 μm, less than or equal to 1.5 μm, less than or equal to 1.2 m, or less than or equal to 1 μm.

The side surface of the insulating layer 110 on the opening 141 side preferably has a tapered shape. The angle θ110 formed by the side surface of the insulating layer 110 on the opening 141 side and the formation surface of the insulating layer 110 (here, the top surface of the conductive layer 112a) is preferably smaller than 90°. By reducing the angle θ110, the coverage with a layer (e.g., the semiconductor layer 108) provided over the insulating layer 110 can be improved. The smaller the angle θ110 is, the larger the channel length L100 is. The larger the angle θ110 is, the smaller the channel length L100 is.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than 90°, less than or equal to 85+θ, or less than or equal to 80°.

In FIG. 3A and FIG. 3B, a width D143 of the opening 143 is indicated by a dashed double-dotted double-headed arrow. FIG. 3A illustrates an example where the top surface shape of each of the opening 141 and the opening 143 is a circle. In this case, the width D143 corresponds to the diameter of the circle and a channel width W100 of the transistor 100 is the length of the circumference of the circle. That is, the channel width W100 is π×D143. Accordingly, in the case where the opening 141 and the opening 143 have circular top surface shapes, the channel width W100 of the transistor can be smaller than in the case where the opening 141 and the opening 143 have any other shape.

Note that the opening 141 and the opening 143 sometimes have different diameters. The inner diameter of each of the opening 141 and the opening 143 sometimes varies in the depth direction. As the diameter of each of the openings, for example, the average value of the following three diameters can be used: the diameter at the highest level of the insulating layer 110 (or an insulating layer 110b) in a cross-sectional view, the diameter at the lowest level of the insulating layer 110 (or the insulating layer 110b) in a cross-sectional view, and the diameter at the midpoint between these levels. For another example, any of the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels can be used as the diameter of each of the openings.

In the case where the opening 143 is formed by a photolithography method, the width D143 of the opening 143 is larger than or equal to the resolution limit of a light-exposure apparatus. The width D143 can be, for example, greater than or equal to 200 nm, greater than or equal to 300 nm, greater than or equal to 400 nm, or greater than or equal to 500 nm and less than 5 m, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

### [Insulating Layer 110]

The insulating layer 110 may have either a single-layer structure or a stacked-layer structure of two or more layers. The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include a silicon nitride and an aluminum nitride. Examples of the oxynitride include silicon oxynitride, aluminum oxynitride, gallium oxynitride, yttrium oxynitride, and hafnium oxynitride film. Examples of the nitride oxide include silicon nitride oxide and aluminum nitride oxide.

Note that in this specification and the like, an oxynitride refers to a material that contains more oxygen than nitrogen in its composition. A nitride oxide refers to a material that contains more nitrogen than oxygen in its composition.

The insulating layer 110 includes a region in contact with the semiconductor layer 108. In the case where the semiconductor layer 108 is formed using an oxide semiconductor, at least part of the region of the insulating layer 110 that is in contact with the semiconductor layer 108 is preferably formed using one or more of an oxide and oxynitride to improve the characteristics of the interface between the semiconductor layer 108 and the insulating layer 110. Specifically, one or more of an oxide and an oxynitride is preferably used for the region of the insulating layer 110 that is in contact with the channel formation region in the semiconductor layer 108.

It is preferable to use one or more of the oxide and oxynitride described above for the insulating layer 110b in contact with the channel formation region of the semiconductor layer 108. Specifically, the insulating layer 110b is preferably formed using one or both of a silicon oxide and a silicon oxynitride.

It is further preferable that a film from which oxygen is released by heating be used as the insulating layer 110b. When the insulating layer 110b releases oxygen by heat applied during the manufacturing process of the transistor 100, the oxygen can be supplied to the semiconductor layer 108. Supplying oxygen from the insulating layer 110b to the semiconductor layer 108, particularly to the channel formation region in the semiconductor layer 108, can allow the amount of oxygen vacancy to be reduced in the semiconductor layer 108, so that a highly reliable transistor having favorable electrical characteristics can be obtained.

For example, the insulating layer 110b can be supplied with oxygen when heat treatment in an atmosphere including oxygen or plasma treatment in an atmosphere including oxygen is performed. Alternatively, an oxide film may be formed by a sputtering method in an atmosphere including oxygen to supply oxygen to the top surface of the insulating layer 110b. After that, the metal oxide film may be removed. Note that Embodiment 2 described later shows an example in which oxygen is supplied to the insulating layer 110b by forming a metal oxide layer 149.

The insulating layer 110b is preferably formed by a film formation method such as a sputtering method or a plasma-enhanced chemical vapor deposition (PECVD) method. In particular, a sputtering method does not need to use a gas including hydrogen as a film formation gas, so that a film having an extremely low hydrogen content can be formed. Consequently, supply of hydrogen to the semiconductor layer 108 is inhibited and the electrical characteristics of the transistor 100 can be stabilized.

The thickness of the insulating layer 110b can be determined in the above range of the thickness of the insulating layer 110 (the thickness T110).

For each of an insulating layer 110a and an insulating layer 110c, a film through which oxygen hardly diffuses is preferably used. Accordingly, it is possible to prevent oxygen included in the insulating layer 110b from being transmitted toward the substrate 102 side through the insulating layer 110a and being transmitted toward the insulating layer 106 side through the insulating layer 110c due to heating. In other words, when the upper and lower sides of the insulating layer 110b are sandwiched between the insulating layer 110a and the insulating layer 110c through which oxygen hardly diffuses, oxygen included in the insulating layer 110b can be enclosed. Thus, oxygen can be effectively supplied to the semiconductor layer 108.

For each of the insulating layer 110a and the insulating layer 110c, a film through which hydrogen hardly diffuses is preferably used. In that case, hydrogen can be inhibited from diffusing from outside the transistor to the semiconductor layer 108 through the insulating layer 110a or the insulating layer 110c.

For the insulating layer 110a and the insulating layer 110c, any one or more of the above-described oxide, nitride, oxynitride, and nitride oxide is preferably used, and any one or more of silicon nitride, silicon nitride oxide, silicon oxynitride, aluminum oxide, aluminum oxynitride, aluminum nitride, hafnium oxide, and hafnium aluminate is preferably used. Silicon nitride and silicon nitride oxide can be particularly suitably used for the insulating layer 110a and the insulating layer 110c because the silicon nitride and the silicon nitride oxide release fewer impurities (e.g., water and hydrogen) and are less likely to transmit oxygen and hydrogen.

The conductive layer 112a and the conductive layer 112b are oxidized by oxygen included in the insulating layer 110b and have high resistance in some cases. Providing the insulating layer 110a between the insulating layer 110b and the conductive layer 112a can inhibit the conductive layer 112a from being oxidized and having high resistance. Similarly, providing the insulating layer 110c between the insulating layer 110b and the conductive layer 112b can inhibit the conductive layer 112b from being oxidized and having high resistance. Accordingly, the amount of oxygen supplied from the insulating layer 110b to the semiconductor layer 108 is increased, whereby the amount of oxygen vacancy in the semiconductor layer 108 can be reduced.

The thicknesses of the insulating layer 110a and the insulating layer 110c are each preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, further preferably larger than or equal to 10 nm and smaller than or equal to 50 nm, further preferably larger than or equal to 20 nm and smaller than or equal to 50 nm, further preferably larger than or equal to 20 nm and smaller than or equal to 40 nm. When the thickness of each of the insulating layer 110a and the insulating layer 110c is in the above-described range, the amount of oxygen vacancies in the semiconductor layer 108, or specifically the channel formation region, can be reduced.

It is preferable that, for example, the insulating layer 110a and the insulating layer 110c be formed using silicon nitride and the insulating layer 110b be formed using a silicon oxynitride.

One or both of a region in contact with the insulating layer 110a and a region in contact with the insulating layer 110c in the semiconductor layer 108 may have higher carrier concentration and lower resistance than the channel formation region. That is, a region of the semiconductor layer 108 that is in contact with the insulating layer 110a and a region of the semiconductor layer 108 that is in contact with the insulating layer 110c each function as a source region or a drain region in some cases. In this case, the effective channel length of the transistor 100 is sometimes shorter than the channel length L100.

For example, when a material that releases impurities (e.g., water and hydrogen) is used for the insulating layer 110a, the semiconductor layer 108 in the region in contact with the insulating layer 110a can function as the source region or the drain region. The same applies to the insulating layer 110c.

### [Conductive Layer 112a, Conductive Layer 112b, and Conductive Layer 104]

The conductive layer 112a, the conductive layer 112b, and the conductive layer 104 may each have a single-layer structure or a stacked-layer structure of two or more layers. The conductive layer 112a, the conductive layer 112b, and the conductive layer 104 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, and the conductive layer 104, a conductive material with low electrical resistivity that includes one or more of copper, silver, gold, and aluminum can be suitably used. Copper or aluminum is particularly preferable because of its high mass-productivity.

As each of the conductive layer 112a, the conductive layer 112b, and the conductive layer 104, a metal oxide (also referred to as a oxide conductor) can be used. Examples of an oxide conductor (OC) include an indium oxide, an zinc oxide, an In—Sn oxide (ITO), an In—Zn oxide, an In—W oxide, an In—W—Zn oxide, an In—Ti oxide, an In—Ti—Sn oxide, an In—Sn—Si oxide (also referred to as an ITO including silicon or an ITSO), an zinc oxide to which gallium is added, and an In—Ga—Zn oxide. An oxide conductor containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

Each of the conductive layer 112a, the conductive layer 112b, and the conductive layer 104 may have a stacked-layer structure of a conductive film including the oxide conductor (the metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, and the conductive layer 104. The use of a Cu—X alloy film enables the manufacturing cost to be reduced because a wet etching method can be used in the processing.

Note that all of the conductive layer 112a, the conductive layer 112b, and the conductive layer 104 may be formed using the same material or at least one of them may be formed using a different material.

Each of the conductive layer 112a and the conductive layer 112b has a region that is in contact with the semiconductor layer 108. In the case where the semiconductor layer 108 is formed using an oxide semiconductor, when the conductive layer 112a or the conductive layer 112b is formed using a metal that is likely to be oxidized (e.g., aluminum), an insulating oxide (e.g., aluminum oxide) is formed between the conductive layer 112a or the conductive layer 112b and the semiconductor layer 108, which might prevent electrical continuity between the conductive layer 112a or a conductive layer 112b and the semiconductor layer 108. Thus, a conductive material that is less likely to be oxidized, a conductive material that maintains low electric resistance even after being oxidized, or an oxide conductive material is preferably used for the conductive layer 112a and the conductive layer 112b.

For example, it is preferable to use titanium, tantalum nitride, titanium nitride, a nitride including titanium and aluminum, a nitride including tantalum and aluminum, ruthenium, ruthenium oxide, ruthenium nitride, an oxide including strontium and ruthenium, an oxide including lanthanum and nickel, or the like as each of the conductive layer 112a and the conductive layer 112b. These materials are preferable because they are conductive materials that are less likely to be oxidized or conductive materials that maintain low electric resistance even when being oxidized. Note that in the case where the conductive layer 112a or the conductive layer 112b has a stacked-layer structure, at least the layer thereof that is in contact with the semiconductor layer 108 is preferably formed using a conductive material that is less likely to be oxidized.

The above-described oxide conductor can be used for each of the conductive layer 112a and the conductive layer 112b. Specifically, an oxide conductor such as indium oxide, zinc oxide, ITO, In—Zn oxide, In—W oxide, In—W—Zn oxide, In—Ti oxide, In—Ti—Sn oxide, In—Sn oxide including silicon, or zinc oxide to which gallium is added can be used.

For each of the conductive layer 112a and the conductive layer 112b, a nitride conductor may be used. Examples of the nitride conductor include tantalum nitride and titanium nitride.

FIG. 1B and the like illustrate a structure in which the conductive layer 112a has a stacked-layer structure of a conductive layer 112a_1 and a conductive layer 112a_2 over the conductive layer 112a_1. As illustrated in FIG. 3B, the conductive layer 112a_2 has an opening 145, and the conductive layer 112a_1 is exposed in the opening 145. In the opening 145, the conductive layer 112a_1 includes a region in contact with the semiconductor layer 108. It is preferable that the conductive layer 112a_2 not include a region in contact with the semiconductor layer 108.

Here, in the case where a conductive material that is less likely to be oxidized is used for the conductive layer 112a and the conductive layer 112b, the resistance thereof might be increased. The conductive layer 112a and the conductive layer 112b function as wirings and thus preferably have low resistance. Moreover, when the conductive layer 112a or the conductive layer 112b is oxidized by oxygen included in the semiconductor layer 108, the amount of oxygen vacancy (V_{O}) and V_{O}H in the semiconductor layer 108 is increased in some cases. In view of this, a conductive material that is less likely to be oxidized is used for the conductive layer 112a_1 including a region in contact with the semiconductor layer 108, and a material with high conductivity (low resistivity) is used for the conductive layer 112a_2 not including a region in contact with the semiconductor layer 108, whereby the resistance of the conductive layer 112a can be reduced. Furthermore, an increase in the amount of oxygen vacancies (V_{O}) and V_{O}H in the semiconductor layer 108 can be inhibited.

Particularly in the case where the channel length L100 is short, oxygen vacancy (V_{O}) and V_{O}H in the channel formation region greatly affect electrical characteristics and reliability. When a conductive material that is less likely to be oxidized is used for the conductive layer 112a_1, an increase in the amount of oxygen vacancy (V_{O}) and V_{O}H in the semiconductor layer 108 can be inhibited. Thus, the transistor with a short channel length can have favorable electrical characteristics and high reliability.

One or more of an oxide conductor and a nitride conductor can be suitably used for the conductive layer 112a_1. For the conductive layer 112a_2, a material having higher conductivity (lower resistivity) than the conductive layer 112a_1 is preferably used. For the conductive layer 112a_2, one or more of copper, aluminum, titanium, tungsten, and molybdenum or an alloy including one or more of these metals as its components can be suitably used, for example. Specifically, In—Sn—Si oxide (ITSO) and tungsten can be suitably used for the conductive layer 112a_1 and the conductive layer 112a_2, respectively.

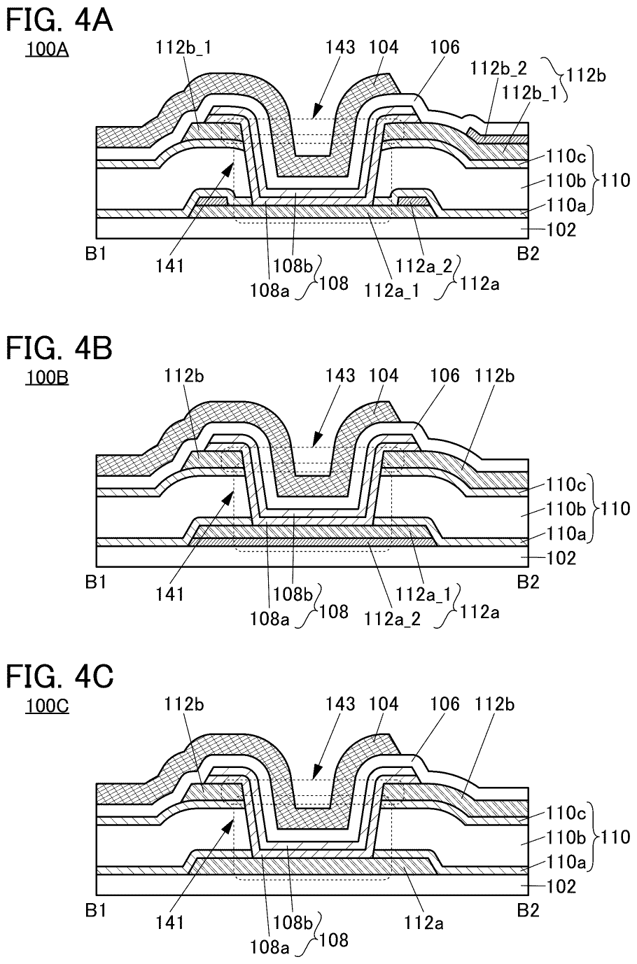

Note that the structure of the conductive layer 112a can be employed for another conductive layer. For example, as in a transistor 100A illustrated in FIG. 4A, the conductive layer 112b can have a stacked-layer structure of a conductive layer 112b_1 and a conductive layer 112b_2 over the conductive layer 112b_1. For the conductive layer 112b_1, a material that can be used for the conductive layer 112a_1 can be used. For the conductive layer 112b_2, a material that can be used for the conductive layer 112a_2 can be used. It is preferable that the semiconductor layer 108 include a region in contact with the conductive layer 112b_1 and not include a region in contact with the conductive layer 112b_2.

Alternatively, as in a transistor 100B illustrated in FIG. 4B, the conductive layer 112a may have a stacked-layer structure of the conductive layer 112a_2 and the conductive layer 112a_1 over the conductive layer 112a_2. The conductive layer 112a_1 includes a region in contact with the semiconductor layer 108. As described above, a conductive material that is less likely to be oxidized is preferably used for the conductive layer 112a_1 that has a region in contact with the semiconductor layer 108. For the conductive layer 112a_2, a material having high conductivity (low resistivity) can be used. With such a structure, the resistance of the conductive layers 112a can be reduced.

Note that the structure of the conductive layer 112a and the conductive layer 112b are determined in accordance with required wiring resistance. In the case where the length of the wiring (e.g., the conductive layer 112a) is short and the wiring resistance required for the conductive layer 112a is relatively high, the conductive layer 112a may have a single-layer structure, and a conductive material that is less likely to be oxidized may be used, as in the transistor 100C illustrated in FIG. 4C. Meanwhile, when the wiring (e.g., the conductive layer 112a) is long and requires relatively low wiring resistance, the conductive layer 112a preferably has a stacked-layer structure of a conductive material that is less likely to be oxidized and a material with high conductivity (low resistivity).

### [Insulating Layer 106]

The insulating layer 106 may have either a single-layer structure or a stacked-layer structure of two or more layers. The insulating layer 106 preferably includes one or more inorganic insulating films. Examples of a material that can be used for the inorganic insulating film include an oxide, a nitride, an oxynitride, and a nitride oxide. For the insulating layer 106, a material that can be used for the insulating layer 110 can be used.

The insulating layer 106 includes a region in contact with the semiconductor layer 108. In the case where the semiconductor layer 108 is formed using an oxide semiconductor, at least the film of the insulating layer 106 that is in contact with the semiconductor layer 108 is preferably any of the above-described oxide and oxynitride. A film from which oxygen is released by heating is further preferably used for the insulating layer 106.

Specifically, in the case where the insulating layer 106 has a single-layer structure, the insulating layer 106 is preferably formed using a silicon oxide or a silicon oxynitride.

The insulating layer 106 can have a stacked-layer structure of a first insulating film on the side in contact with the semiconductor layer 108 and a second insulating film on the side in contact with the conductive layer 104. An oxide or an oxynitride can be used for the first insulating film, and for example, silicon oxide or silicon oxynitride is preferably used. A nitride or a nitride oxide can be used for the second insulating film, and for example, silicon nitride or silicon nitride oxide is preferably used.

Silicon nitride and silicon nitride oxide can be suitably used for the insulating layer 106 because the silicon nitride and the silicon nitride oxide release fewer impurities (e.g., water and hydrogen) and are less likely to transmit oxygen and hydrogen. Inhibiting diffusion of impurities from the insulating layer 106 to the semiconductor layer 108 results in favorable electrical characteristics and high reliability of the transistor.

A transistor having a minute size and including a thin gate insulating layer may have a large leakage current. When a high dielectric constant material (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In such a case, the transistor 100 and the like can be transferred to a substrate having low heat resistance or a flexible substrate as well.

A structure example which is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 2

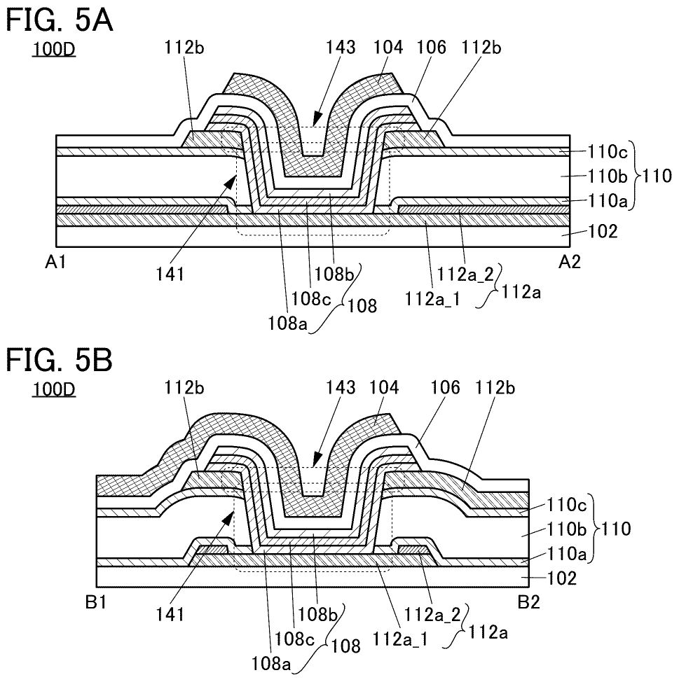

FIG. 5A and FIG. 5B illustrate cross-sectional views of a transistor 100D that can be used in the semiconductor device of one embodiment of the present invention. FIG. 1A can be referred to for a top view of the transistor 100D. FIG. 5A is a cross-sectional view of a cut plane along the dashed-dotted line A1-A2 in FIG. 1A, and FIG. 5B is a cross-sectional view of a cut plane along the dashed-dotted line B1-B2.

The transistor 100D is different from the transistor 100 illustrated in FIG. 1B mainly in that the semiconductor layer 108 includes a semiconductor layer 108c.

The semiconductor layer 108 has a three-layer structure of the semiconductor layer 108a, the semiconductor layer 108c over the semiconductor layer 108a, and the semiconductor layer 108b over the semiconductor layer 108c. The semiconductor layer 108c is provided between the semiconductor layer 108a and the semiconductor layer 108b.

For the semiconductor layer 108c, a material that can be used for the semiconductor layer 108 can be used. The semiconductor layer 108a, the semiconductor layer 108b, and the semiconductor layer 108c may be formed using the same material or different materials.

The conductivity of a material used for the semiconductor layer 108c is preferably different from the conductivity of a material used for the semiconductor layer 108a. The conductivity of a material used for the semiconductor layer 108c is preferably different from the conductivity of a material used for the semiconductor layer 108b.

For example, a material having higher conductivity than the semiconductor layer 108c can be used for the semiconductor layer 108a. The use of the material having high conductivity for the oxide semiconductor layer 108a that is in contact with the conductive layer 112a and the conductive layer 112b can reduce the contact resistance between the semiconductor layer 108 and the conductive layer 112a and the contact resistance between the semiconductor layer 108 and the conductive layer 112b, so that the transistor can have high on-state current. For the semiconductor layer 108b, a material having lower conductivity than the semiconductor layer 108c can be used. Thus, a normally-off transistor can be obtained.

Note that a material having lower conductivity than the semiconductor layer 108c may be used for the semiconductor layer 108a. For the semiconductor layer 108b, a material having higher conductivity than the semiconductor layer 108c may be used.

Each of the semiconductor layer 108a, the semiconductor layer 108b, and the semiconductor layer 108c preferably contains a metal oxide (also referred to as an oxide semiconductor).

The bandgap of a third metal oxide used for the semiconductor layer 108c is preferably greater than or equal to 2.0 eV, further preferably greater than or equal to 2.5 eV.

The first metal oxide used for the semiconductor layer 108a and the third metal oxide used for the semiconductor layer 108c preferably have different band gaps. The second metal oxide used for the semiconductor layer 108b and third metal oxide used for the semiconductor layer 108c preferably have different band gaps.

For example, the band gap of the first metal oxide used for the semiconductor layer 108a can be smaller than the band gap of the third metal oxide used for the semiconductor layer 108c. Thus, the contact resistance between the semiconductor layer 108 and the conductive layer 112a and the contact resistance between the semiconductor layer 108 and the conductive layer 112b can be reduced, so that the transistor can have high on-state current. The band gap of the second metal oxide used for the semiconductor layer 108b can be larger than the band gap of the third metal oxide used for the semiconductor layer 108c. Thus, a normally-off transistor can be obtained.

Note that the band gap of the first metal oxide may be larger than that of the third metal oxide. The band gap of the second metal oxide may be smaller than that of the third metal oxide.

Different compositions of the first metal oxide to the third metal oxide can control the band gap. The composition of the third metal oxide is preferably different from that of the first metal oxide. The composition of the third metal oxide is preferably different from that of the second metal oxide. For example, the content percentage of the element M in the third metal oxide can be higher than that of the element M in the first metal oxide. The content percentage of the element M in the third metal oxide can be lower than that of the element M in the second metal oxide.

Note that the content percentage of the element M in the third metal oxide may be lower than that of the element M in the first metal oxide. The content percentage of the element M in the third metal oxide may be higher than that of the element M in the second metal oxide.

The compositions of the first metal oxide to the third metal oxide may be the same or substantially the same as each other. Employing the metal oxides having the same composition can reduce the manufacturing cost because the metal oxide can be formed using the same sputtering target. Here, the degree of crystallinity of the semiconductor layer 108c is preferably different from the degree of crystallinity of the semiconductor layer 108a. The degree of crystallinity of the semiconductor layer 108c is preferably different from the degree of crystallinity of the semiconductor layer 108b. For example, the crystallinity of the semiconductor layer 108a is preferably lower than the crystallinity of the semiconductor layer 108c. Thus, the contact resistance between the semiconductor layer 108 and the conductive layer 112a and the contact resistance between the semiconductor layer 108 and the conductive layer 112b can be reduced, so that the transistor can have high on-state current. By contrast, the crystallinity of the semiconductor layer 108b is preferably higher than that of the semiconductor layer 108c. Accordingly, a normally-off transistor can be obtained.

Note that the crystallinity of the semiconductor layer 108c may be lower than that of the semiconductor layer 108a. The crystallinity of the semiconductor layer 108c may be higher than that of the semiconductor layer 108b.

FIG. 5A and FIG. 5B illustrate an example in which end portions of the semiconductor layer 108a, the semiconductor layer 108b, and the semiconductor layer 108c are aligned or substantially aligned with each other. The semiconductor layer 108a, the semiconductor layer 108b, and the semiconductor layer 108c can be formed using the same resist mask. The process can be simplified by using the same resist mask. Thus, the semiconductor layer 108a, the semiconductor layer 108b, and the semiconductor layer 108c that have substantially the same top surface shapes can be formed. Note that end portions of the semiconductor layer 108a, the semiconductor layer 108b, and the semiconductor layer 108c are not necessarily aligned with each other.

### Structure Example 3

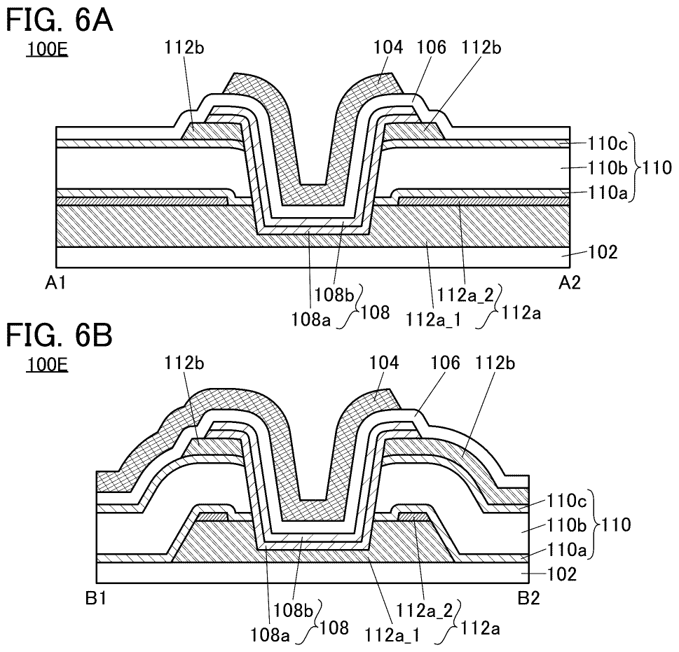

FIG. 6A and FIG. 6B illustrate cross-sectional views of a transistor 100E that can be used in the semiconductor device of one embodiment of the present invention. FIG. 1A can be referred to for a top view of the transistor 100E. FIG. 6A is a cross-sectional view of the cut plane along the dashed-dotted line A1-A2 in FIG. 1A, and FIG. 6B is a cross-sectional view of the cut plane along the dashed-dotted line B1-B2.

The transistor 100E is different from the transistor 100 illustrated in FIG. 1B and the like mainly in that the thickness of a region of the conductive layer 112a_1 that is in contact with the bottom surface of the semiconductor layer 108 is different from the thickness of a region of the conductive layer 112a_1 that is not in contact with the semiconductor layer 108.

As illustrated in FIG. 6A and the like, the thickness of the region of the conductive layer 112a_1 that is in contact with the bottom surface of the semiconductor layer 108 is preferably smaller than the thickness of the region that is not in contact with the semiconductor layer 108 in the conductive layer 112a_1.

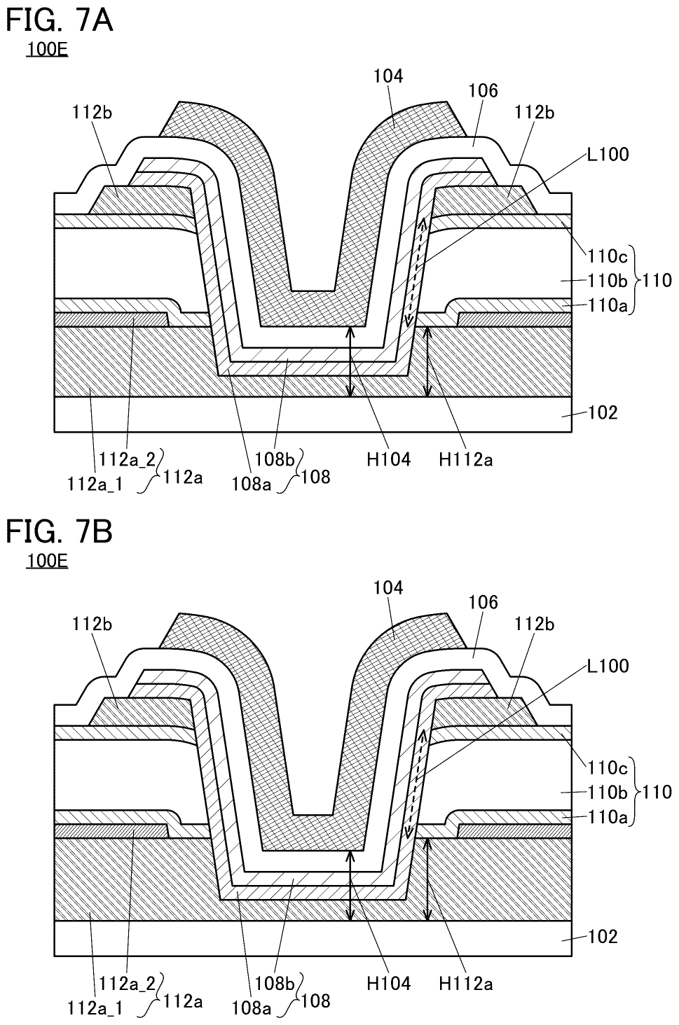

FIG. 7A and FIG. 7B are enlarged views of FIG. 6A. FIG. 7A illustrates a height H104 from the formation surface of the conductive layer 112a_1 (here, the top surface of the substrate 102) to the lowest position of the bottom surface of the conductive layer 104. FIG. 6A also illustrates a height H112a from the formation surface of the conductive layer 112a_1 (here, the top surface of the substrate 102) to the highest position of the region where the conductive layer 112a_1 and the semiconductor layer 108 are in contact with each other. As illustrated in FIG. 7A, the height H104 to the lowest position of the bottom surface of the conductive layer 104 is preferably equal to or substantially equal to the height H112a to the highest position of the region where the conductive layer 112a_1 and the semiconductor layer 108 are in contact with each other. Alternatively, as illustrated in FIG. 7B, the height H104 is preferably smaller than the height H112a. When the height H104 to the lowest position of the bottom surface of the conductive layer 104 is equal to the height H112a to the highest position of the region where the conductive layer 112a_1 and the semiconductor layer 108 are in contact with each other or smaller than the height H112a, the electric field of the gate electrode that is applied to the channel formation region in the vicinity of the conductive layer 112a can be increased and the on-state current of the transistor 100E can be increased.

When the height H104 to the lowest position of the bottom surface of the conductive layer 104 is equal to the height H112a to the highest position of the region where the conductive layer 112a_1 and the semiconductor layer 108 are in contact with each other or smaller than the height H112a, the electric field of the gate electrode applied to the channel formation region can be more uniform. Here, in the case where the electric field of the gate electrode applied to the channel formation region is not uniform, the electrical characteristics in the case where the conductive layer 112a is the source electrode and the conductive layer 112b is the drain electrode and the electrical characteristics in the case where the conductive layer 112a is the drain electrode and the conductive layer 112b is the source electrode might be different from each other. By making the electric field of the gate electrode applied to the channel formation region of the transistor 100E more uniform, the electrical characteristics in the both cases can be made equivalent to each other. Thus, the transistor 100E can be suitably used in a circuit structure in which a source and a drain are interchanged with each other.

Note that the thickness of the conductive layer 112a (specifically, the conductive layer 112a_1) is adjusted as appropriate so that the height H104 is equal to the height H112a or smaller than the height H112a.

### Structure Example 4

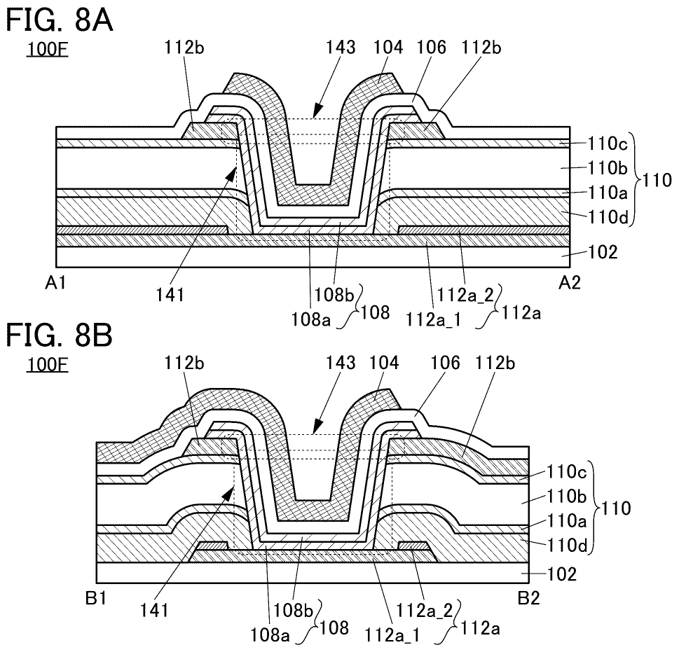

FIG. 8A and FIG. 8B illustrate cross-sectional views of a transistor 100F that can be used in the semiconductor device of one embodiment of the present invention. FIG. 1A can be referred to for a top view of the transistor 100F. FIG. 8A is a cross-sectional view of the cut plane along the dashed-dotted line A1-A2 in FIG. 1A, and FIG. 8B is a cross-sectional view of the cut plane along the dashed-dotted line B1-B2.

The transistor 100F is different from the transistor 100 illustrated in FIG. 1B and the like mainly in that the insulating layer 110 includes an insulating layer 110d.

The insulating layer 110 includes the insulating layer 110d, the insulating layer 110a over the insulating layer 110d, the insulating layer 110b over the insulating layer 110a, and the insulating layer 110c over the insulating layer 110b.

The insulating layer 110d includes a region in contact with the semiconductor layer 108 and the conductive layer 112a. The insulating layer 110d preferably includes a region including more hydrogen than the insulating layer 110a. Similarly, the insulating layer 110d preferably includes a region including more hydrogen than the insulating layer 110b. The insulating layer 110d preferably includes a region including more hydrogen than the insulating layer 110c. Moreover, the insulating layer 110d preferably releases hydrogen from itself by heat applied during the process.

The hydrogen content of each of the insulating layer 110a, the insulating layer 110b, the insulating layer 110c, and the insulating layer 110d can be analyzed by secondary ion mass spectrometry (SIMS), for example.

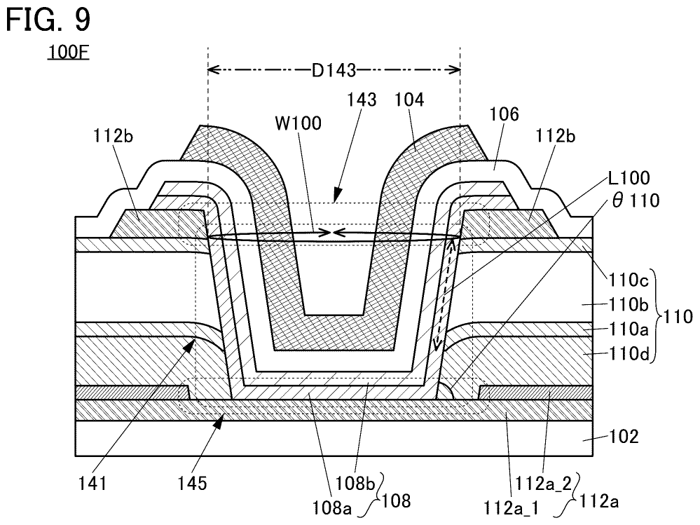

FIG. 9 is an enlarged view of FIG. 8A. By providing the insulating layer 110d, hydrogen is supplied from the insulating layer 110d to the region of the semiconductor layer 108 in contact with the insulating layer 110d, so that the resistance of the region becomes low. The region (hereinafter also referred to as a low-resistance region) can function as a source region or a drain region. Providing the low-resistance region on the conductive layer 112a side in the semiconductor layer 108 can make the distance from the source region to the gate electrode and the distance from the drain region to the gate electrode more uniform. Thus, the electric field of the gate electrode applied to the channel formation region can be more uniform.

For the insulating layer 110d, a material that can be used for the insulating layer 110 described above can be used. In particular, for the insulating layer 110d, a material that can be used for the insulating layer 110a and the insulating layer 110c described above can be used. For the insulating layer 110d, one or more of silicon nitride, silicon nitride oxide, silicon oxynitride, aluminum oxide, aluminum oxynitride, aluminum nitride, hafnium oxide, and hafnium aluminate are preferably used. Note that for the insulating layer 110a, the insulating layer 110c, and the insulating layer 110d, the same material or different materials may be used.

The film formation gas used for the formation of the insulating layer 110d preferably includes more hydrogen than the film formation gas used for the formation of the insulating layer 110a. Specifically, in the case of using a PECVD method for forming the insulating layer 110, the proportion of a flow rate of an ammonia gas to the whole film formation gas used for forming the insulating layer 110d (hereinafter also referred to as ammonia flow rate ratio) is preferably higher than the proportion of a flow rate of an ammonia gas to the whole film formation gas used for forming the insulating layer 110a. The formation of the insulating layer 110d under the condition where the ammonia flow rate ratio is high can increase the hydrogen content in the insulating layer 110d. Furthermore, the amount of hydrogen released from the insulating layer 110d due to heat applied thereto can be increased. Similarly, the film formation gas used for the formation of the insulating layer 110d preferably includes more hydrogen than the film formation gas used for the formation of the insulating layer 110c. Specifically, the ammonia flow rate ratio of the film formation gas used for the formation of the insulating layer 110d is preferably higher than the ammonia flow rate ratio of the film formation gas used for the formation of the insulating layer 110c.

Here, the insulating layer 110a and the insulating layer 110c preferably release a small amount of hydrogen from itself and further preferably less likely transmit hydrogen. Meanwhile, the insulating layer 110d preferably releases a large amount of hydrogen from itself. When the film formation conditions for the insulating layer 110a and the insulating layer 110c are different from those for the insulating layer 110d, the amount of released hydrogen can be adjusted. Specifically, the film formation conditions for the insulating layer 110a and the insulating layer 110c are different from those for the insulating layer 110d in any one or more of a film formation power (film formation power density), a film formation pressure, the kind of a film formation gas, the flow rate ratio of a film formation gas, a film formation temperature, and the distance between the substrate and an electrode during formation. For example, the film formation power density for the insulating layer 110d may be lower than those for the insulating layer 110a and the insulating layer 110c, in which case the insulating layer 110d can have a higher hydrogen content than the insulating layer 110a and the insulating layer 110c. Accordingly, the amount of hydrogen released from the insulating layer 110d due to heat applied thereto can be increased.

Providing the insulating layer 110a that less likely transmits hydrogen between the insulating layer 110d and the insulating layer 110b can inhibit diffusion of hydrogen released from the insulating layer 110d into the insulating layer 110b. This inhibits hydrogen from diffusing into the channel formation region of the semiconductor layer 108 through the insulating layer 110b, whereby the transistor can have excellent electrical characteristics and high reliability.

The film density of the insulating layer 110a is preferably higher than that of the insulating layer 110d. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Thus, the transmission electron (TE) image of the insulating layer 110a is a dark-colored (dark) image compared to the insulating layer 110d in some cases. Note that since the insulating layer 110a and the insulating layer 110d have different film densities even when including the same materials, it is sometimes possible to identify the boundary between the insulating layer 110a and the insulating layer 110d by a difference in contrast in a TEM image of a cross section.

### Structure Example 5

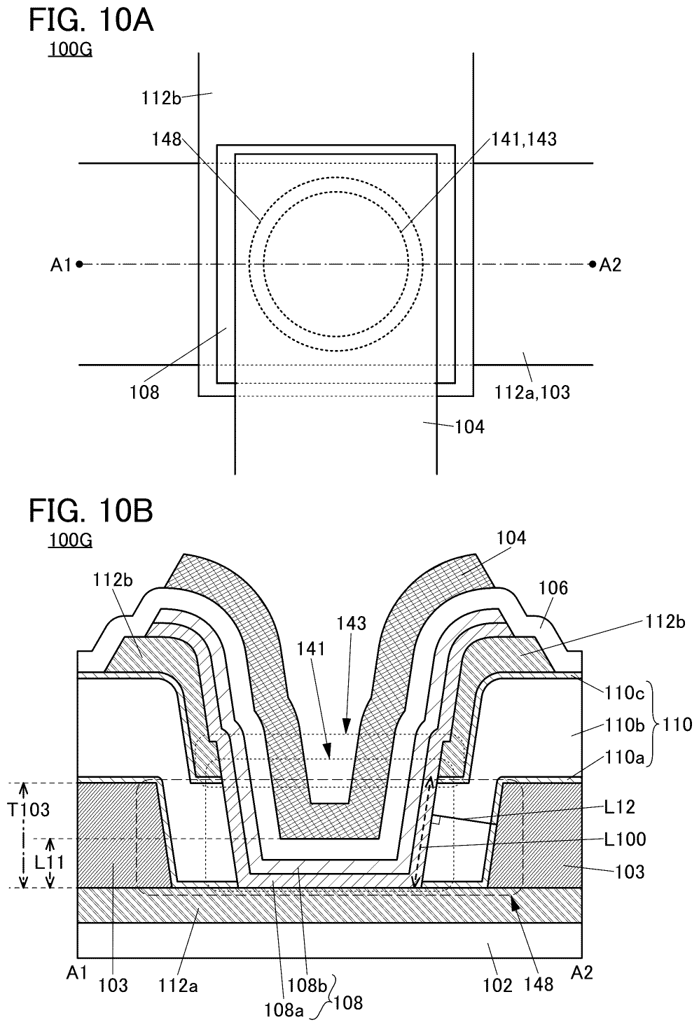

FIG. 10A illustrates a top view of a transistor 100G that can be used in the semiconductor device of one embodiment of the present invention. FIG. 10B is a cross-sectional view of the cut plane along the dashed-dotted line A1-A2 in the transistor 100G.

The transistor 100G is different from the transistor 100C illustrated in FIG. 4C mainly in including a conductive layer 103 between the conductive layer 112a and the insulating layer 110.

The conductive layer 103 is provided over and in contact with the conductive layer 112a. The conductive layer 103 is provided with an opening 148 reaching the conductive layer 112a. There is no particular limitation on the top surface shape of the opening 148. Note that the top surface shape of the opening 148 refers to the shape of the end portion of the top surface or the bottom surface of the conductive layer 103 on the opening 148 side.

The insulating layer 110 is positioned over the substrate 102, the conductive layer 112a, and the conductive layer 103. The insulating layer 110 is provided to cover part of the opening 148. The insulating layer 110 is in contact with the conductive layer 112a through the opening 148. In the insulating layer 110, the opening 141 which reaches the conductive layer 112a is positioned inside the opening 148.

It can be said that as shown in FIG. 10B, the thickness T103 of the conductive layer 103 is the shortest distance from the top surface of the conductive layer 112a to the top surface of the conductive layer 103. The thickness T103 of the conductive layer 103 is larger than a distance L11 which is the shortest distance from the top surface of the conductive layer 112a to the bottom surface of the conductive layer 104 in the opening 141. Moreover, in a cross-sectional view, the bottom surface of the conductive layer 104 inside the opening 141 is at a lower level (the substrate 102 side) than the top surface of the conductive layer 103 is. Accordingly, the semiconductor layer 108 includes a region overlapping with the conductive layer 104 with the insulating layer 106 therebetween and overlapping with the conductive layer 103 with the insulating layer 110 therebetween. That is, the conductive layer 103 includes a region overlapping with the conductive layer 104 with the insulating layer 110, the semiconductor layer 108, and the insulating layer 106 therebetween. Thus, the conductive layer 103 can function as a back gate electrode (also referred to as a second gate electrode) of the transistor 100G. In this case, the insulating layer 110 functions as a back gate insulating layer (also referred to as a second gate insulating layer) of the transistor 100D.

By providing the back gate electrode in the transistor 100G, the potential of the semiconductor layer 108 on the back channel side can be fixed. Thus, the saturation of the I_{d}-V_{d} characteristics of the transistor 100G can be improved.

In this specification and the like, the state where the change in current is small (the slope is gentle) in the saturation region of the I_{d}-V_{d} characteristics of a transistor is sometimes described using the expression “favorable saturation”.

The conductive layer 103 and the conductive layer 112a, which are in contact with each other, are supplied with the same potential. The conductive layer 103, which functions as the back gate electrode, is preferably supplied with the lower potential of the source potential and the drain potential. Thus, in the case where the transistor 100G is an n-channel transistor, it is preferable that the conductive layer 112a function as a source electrode and the conductive layer 112b function as a drain electrode. In the case where the transistor 100G is a p-channel transistor, it is preferable that the conductive layer 112a function as the drain electrode and the conductive layer 112b function as the source electrode.

In general, a transistor with a short channel length tends to have poor saturation of I_{d}-V_{d} characteristics; however, the transistor 100G can have favorable saturation because of including the back gate electrode.

The thickness T103 of the conductive layer 103 is preferably 0.5 or more times the channel length L100, further preferably 1.0 or more times the channel length L100, still further preferably more than 1.0 times the channel length L100. In that case, the region overlapping with the conductive layer 104 with the insulating layer 106 therebetween and overlapping with the conductive layer 103 with the insulating layer 110 therebetween can be wide. As a result, the electric field of the semiconductor layer 108 on the back channel side can be controlled more reliably.

The transistor 100G includes a region where the conductive layer 103, the insulating layer 110, the semiconductor layer 108, the insulating layer 106, and the conductive layer 104 are stacked in this order in one direction with no any other layer included between these layers. The one direction can be perpendicular to the channel length L100 direction. When the above region is wide, the electric field of the semiconductor layer 108 on the back channel side can be controlled more reliably.

A distance L12, which is the shortest distance between the conductive layer 103 and the semiconductor layer 108, is preferably shorter than the channel length L100, further preferably 0.5 or less times the channel length L100, still further preferably 0.1 or less times the channel length L100. The shorter the distance between the conductive layer 103 and the semiconductor layer 108 is, the more favorable the saturation of the I_{d}-V_{d} characteristics of the transistor 100G can be.

### Structure Example 6

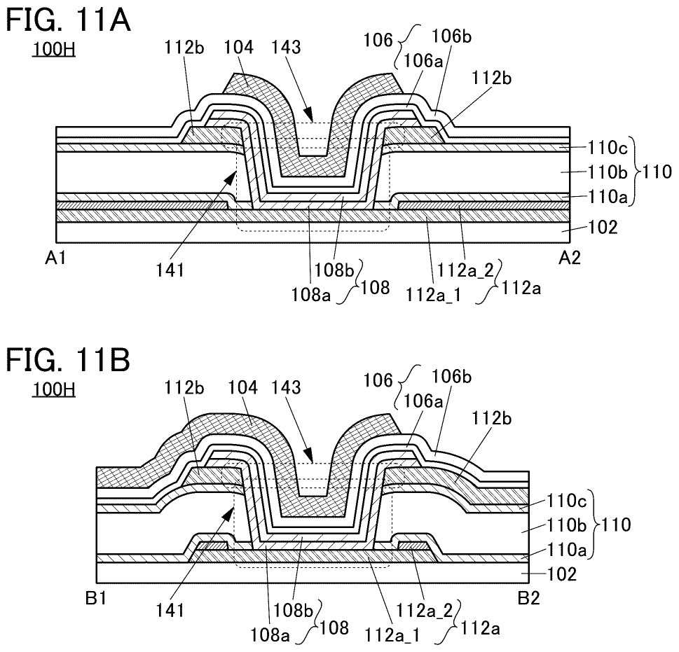

FIG. 11A and FIG. 11B illustrate cross-sectional views of a transistor 100H that can be used in the semiconductor device of one embodiment of the present invention. Note that FIG. 1A can be referred to for a top view of the transistor 100H. FIG. 11A is a cross-sectional view of a cut plane along the dashed-dotted line A1-A2 in FIG. 1A, and FIG. 11B is a cross-sectional view of a cut plane along the dashed-dotted line B1-B2.

The transistor 100H is different from the transistor 100 illustrated in FIG. 1B and the like mainly in that the insulating layer 106 has a stacked-layer structure.

The insulating layer 106 includes an insulating layer 106a and an insulating layer 106b over the insulating layer 106a. For each of the insulating layer 106a and the insulating layer 106b, the above-described material that can be used for the insulating layer 106 can be used. Note that although an example where the insulating layer 106 has a two-layer structure is described here, one embodiment of the present invention is not limited to this. The insulating layer 106 may have a stacked-layer structure of three or more layers.

It is preferable to use an aluminum oxide film as the insulating layer 106a. Examples of a method for forming the aluminum oxide film include an ALD method, a sputtering method using an aluminum oxide target, and a reactive sputtering method using an aluminum target. An ALD method is preferably used, in which case a dense film with few cracks and pinholes can be formed. The use of a sputtering method is preferable because of its high productivity. Alternatively, for example, an aluminum oxide film may be formed in the following manner: an aluminum film with a thickness greater than or equal to 0.1 nm and less than or equal to 5 nm is formed, and then the aluminum film is oxidized.

When an aluminum oxide film is used as the insulating layer 106a in contact with the semiconductor layer 108, aluminum can exist at an interface between the insulating layer 106 and the semiconductor layer 108 and in the vicinity thereof. Specifically, aluminum might exist at an interface between the insulating layer 106 and the semiconductor layer 108a and in the vicinity thereof and at an interface between the insulating layer 106 and the semiconductor layer 108b and in the vicinity thereof. In addition, aluminum enters the semiconductor layer 108 in some cases. For example, in the case where IGZO is used for the semiconductor layer 108b, part of the semiconductor layer 108b sometimes includes IGZAO by the entry of aluminum into the surface of the IGZO and the vicinity thereof. Thus, the semiconductor layer 108b apparently has a stacked-layer structure of IGZO and IGZAO and has a wider band gap than the single-layer structure of IGZO; in other word, the semiconductor layer 108b is a wide gap. When the band gap of the semiconductor layer 108b is widened, the off-state current of the transistor can be reduced. Furthermore, a region of the semiconductor layer 108a that is in contact with the insulating layer 106 includes IGZAO in some cases.

It is preferable to use, for example, a silicon oxynitride film as the insulating layer 106b. The silicon oxynitride film can be formed by a PECVD method, for example.

This embodiment can be combined with the other embodiments as appropriate. In this specification, in the case where a plurality of structure examples are shown in one embodiment, the structure examples can be combined as appropriate.

### Embodiment 2

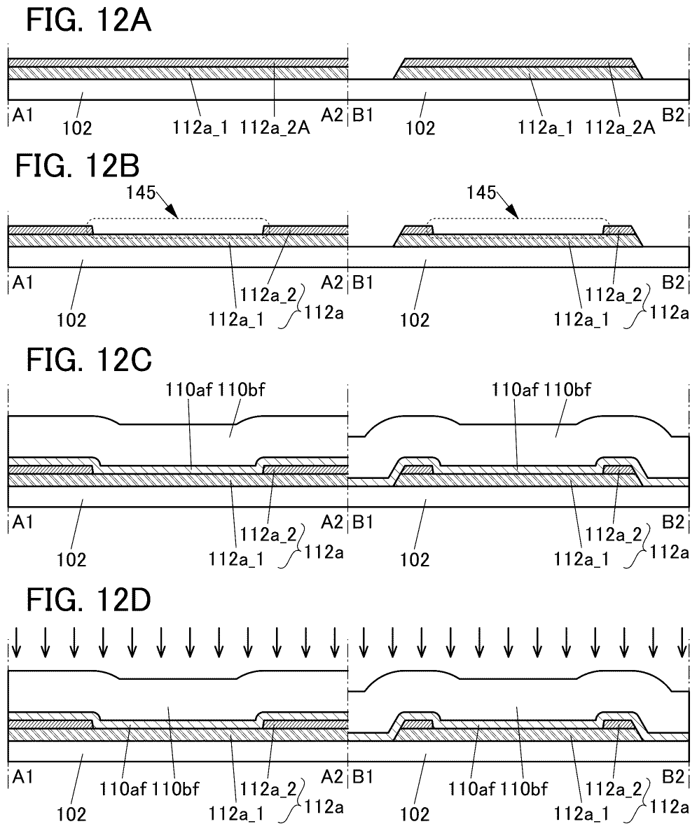

In this embodiment, a method for manufacturing a semiconductor device of one embodiment of the present invention will be described with reference to FIG. 12A to FIG. 15B. Note that as for a material and a formation method of each component, portions similar to the portions described in Embodiment 1 are not described in some cases.

FIG. 12A to FIG. 15B each illustrate, side by side, a cross section along the dashed-dotted line A1-A2 and a cross section along the dashed-dotted line B1-B2 in FIG. 1A.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. As an example of the thermal CVD method, a metal organic chemical vapor deposition (MOCVD: Metal Organic CVD) method can be given.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films that form the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. In addition, light exposure may be performed by liquid immersion exposure technique. As the light used for the light exposure, extreme ultraviolet (EUV) light, X-rays, or the like may be used. Instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

First, a first conductive film to be the conductive layer 112a_1 and a second conductive film to be the conductive layer 112a_2 are formed over the substrate 102 and then processed to form the conductive layer 112a_1 and the conductive layer 112a_2A (FIG. 12A). The conductive layer 112a_2A becomes the conductive layer 112a_2 later. For the formation of the first conductive film and the second conductive film, a sputtering method can be suitably used, for example. For the processing of the first conductive film and the second conductive film, either one or both of a wet etching method and a dry etching method can be used.

Next, part of the conductive layer 112a_2A is removed, so that the conductive layer 112a_2 having the opening 145 is formed (FIG. 12B). Accordingly, the conductive layer 112a functioning as one of the source electrode and the drain electrode of the transistor 100 is formed. For the formation of the opening 145, one or both of a wet etching method and a dry etching method can be used.

Note that although an example in which the opening 145 is formed after the conductive layer 112a_2A is formed is described here, one embodiment of the present invention is not limited thereto. After the opening 145 is formed in the second conductive film, the second conductive film may be processed into the conductive layer 112a_2.

Next, an insulating film 110af to be the insulating layer 110a and an insulating film 110bf to be the insulating layer 110b are formed over the conductive layer 112a (FIG. 12C).

A sputtering method or a PECVD method, for example, is suitable for the formation of the insulating film 110af and the insulating film 110bf. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, the transistor can have favorable electrical characteristics and high reliability.

Note that since the insulating film 110af and the insulating film 110bf are formed earlier than the semiconductor layer 108, there is no need to consider the probability of oxygen release from the semiconductor layer 108 due to heat applied thereto at the time of forming the insulating film 110af and the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include PECVD apparatus, a plasma etching apparatus, and a plasma ashing apparatus. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide. FIG. 12D schematically illustrates a state where oxygen is supplied to the insulating film 110bf by arrows.

Note that the plasma treatment may be successively performed in a vacuum without exposure of the surface of the insulating film 110bf to the air. For example, in the case where a PECVD apparatus is used to form the insulating film 110bf, the plasma treatment is preferably performed with the PECVD apparatus. Accordingly, the productivity can be increased.

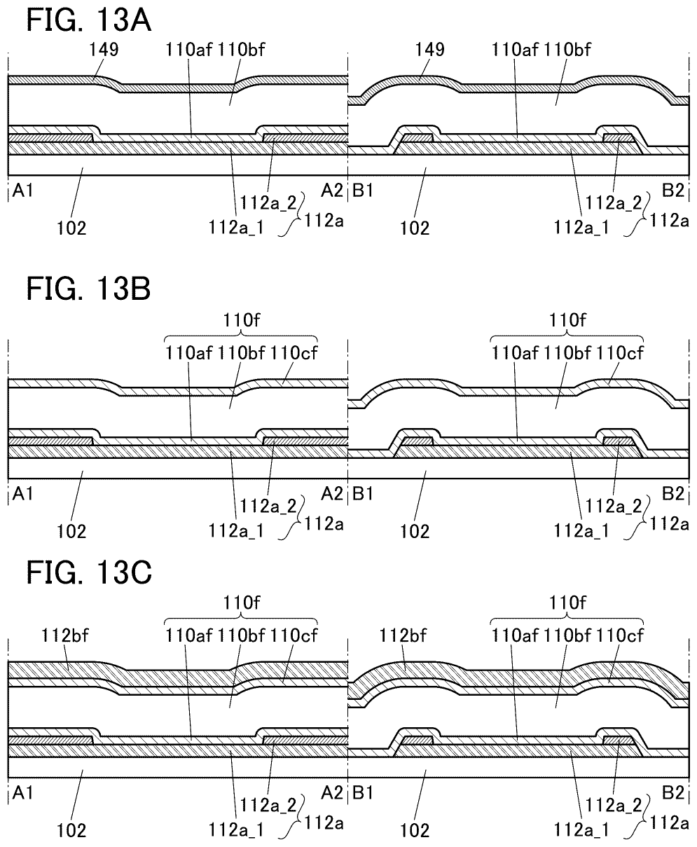

Next, the metal oxide layer 149 is preferably formed over the insulating film 110bf (FIG. 13A). The formation of the metal oxide layer 149 enables oxygen supply to the insulating film 110bf.

There is no limitation on the conductivity of the metal oxide layer 149. As the metal oxide layer 149, at least one of an insulating film, a semiconductor film, and a conductive film can be used. For the metal oxide layer 149, aluminum oxide, hafnium oxide, hafnium aluminate, indium oxide, indium tin oxide (ITO), or indium tin oxide including silicon (ITSO) can be used, for example.

For the metal oxide layer 149, an oxide material including one or more elements that are the same as those of the semiconductor layer 108 is preferably used. It is particularly preferable to use an oxide semiconductor material that can be used for the semiconductor layer 108.

At the time of forming the metal oxide layer 149, the amount of oxygen supplied into the insulating film 110bf can be increased with a higher flow rate ratio of an oxygen gas of the film formation gas introduced into a processing chamber of a film formation apparatus or with higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 149 is formed by a sputtering method in an atmosphere including oxygen in the above manner, oxygen can be supplied to the insulating film 110bf and release of oxygen from the insulating film 110bf can be prevented during the formation of the metal oxide layer 149. As a result, a large amount of oxygen can be enclosed in the insulating film 110bf. Moreover, a large amount of oxygen can be supplied to the semiconductor layer 108 by heat treatment performed later. As a result, the amount of oxygen vacancy and V_{O}H in the semiconductor layer 108 can be reduced, so that a highly reliable transistor exhibiting favorable electrical characteristics can be obtained.

After the metal oxide layer 149 is formed, heat treatment may be performed. By the heat treatment performed after the formation of the metal oxide layer 149, oxygen can be effectively supplied from the metal oxide layer 149 to the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere including one or more of a noble gas, nitrogen, and oxygen. As an atmosphere including nitrogen or an atmosphere including oxygen, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. The use of the RTA apparatus can shorten the heat treatment time.

After the formation of the metal oxide layer 149 or after the above-described heat treatment, oxygen may be further supplied to the insulating film 110bf through the metal oxide layer 149. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 149 is removed. There is no particular limitation on a method for removing the metal oxide layer 149, and a wet etching method can be suitably used. With use of a wet etching method, the insulating film 110bf can be inhibited from being etched during the removal of the metal oxide layer 149. This can inhibit a reduction in the thickness of the insulating film 110bf and the thickness of the insulating layer 110b can be uniform.

The treatment for supplying oxygen to the insulating film 110bf is not necessarily performed in the above-described manner. An oxygen radical, an oxygen atom, an oxygen atomic ion, an oxygen molecular ion, or the like is supplied to the insulating film 110bf by an ion doping method, an ion implantation method, plasma treatment, or the like. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, an insulating film 110cf to be the insulating layer 110c is formed over the insulating film 110bf (FIG. 13B). The description of the formation of the insulating film 110af and the insulating film 110bf can be referred to for the formation of the insulating film 110cf; thus, the detailed description thereof is omitted. Thus, the insulating film 110f having a stacked-layer structure of the insulating film 110af, the insulating film 110bf, and the insulating film 110cf is formed. The insulating film 110f is a film to be the insulating layer 110 later.

Then, a conductive film 112bf to be the conductive layer 112b is formed over the insulating film 110cf (FIG. 13C). For the formation of the conductive film 112bf, a sputtering method can be suitably used, for example.

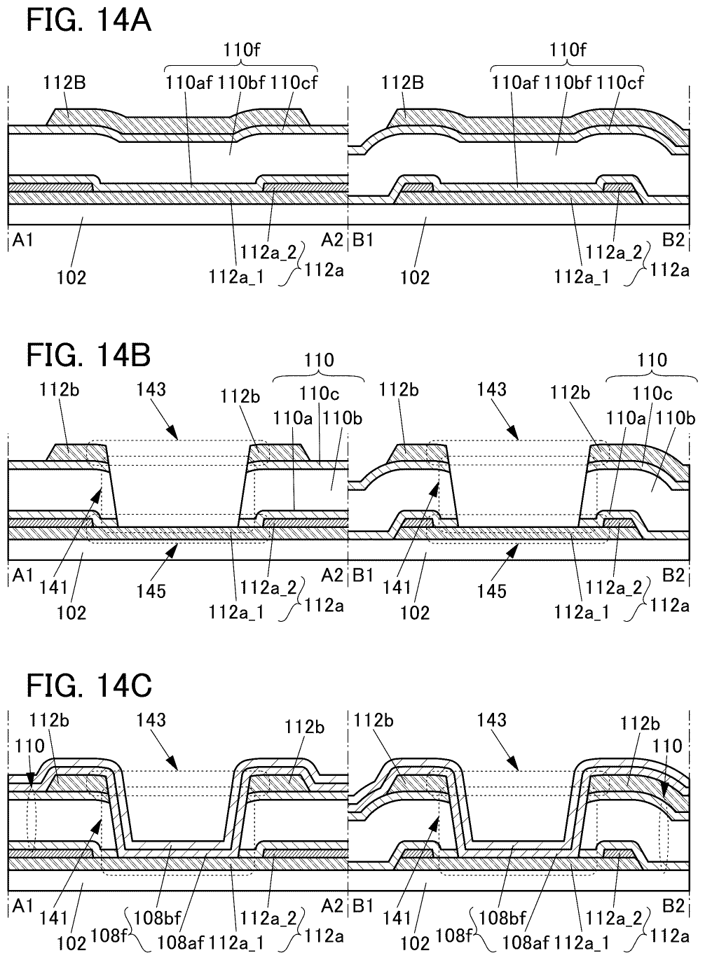

Next, the conductive film 112bf is processed to form the conductive layer 112B (FIG. 14A). The conductive layer 112B becomes the conductive layer 112b later. For the formation of the conductive layer 112B, a wet etching method can be suitably used, for example.

Next, the conductive layer 112B is partly removed, whereby the conductive layer 112b having the opening 143 is formed. The opening 143 is provided in a region overlapping with the opening 145. For the formation of the conductive layer 112b, either one or both of a wet etching method and a dry etching method can be used. In particular, a wet etching method can be suitably used.

Next, the insulating film 110f is partly removed, whereby the insulating layer 110 having the opening 141 is formed (FIG. 14B). The opening 141 is provided in a region overlapping with the opening 143. The opening 141 is provided in a region overlapping with the opening 145, and the conductive layer 112a_1 is exposed by the formation of the opening 141. For the formation of the insulating layer 110, either one or both of a wet etching method and a dry etching method can be used. In particular, a dry etching method can be suitably used.

The opening 141 can be formed using a resist mask used for the formation of the opening 143, for example. Specifically, a resist mask is formed over the conductive layer 112B, the conductive layer 112B is partly removed with use of the resist mask to form the opening 143, and the insulating film 110f is partly removed with use of the resist mask, whereby the opening 141 can be formed. The opening 143 may be formed using a resist mask that is different from the resist mask used for the formation of the opening 141.

Note that in the formation of the opening 141 or after the formation of the opening 141, part of the conductive layer 112a (specifically, the conductive layer 112a_1) in a region overlapping with the opening 141 may be removed. Accordingly, the structure illustrated in FIG. 7A and FIG. 7B can be achieved.

Subsequently, a metal oxide film 108f to be the semiconductor layer 108 is formed to cover the opening 141 and the opening 143 (FIG. 14C). Here, as the metal oxide film 108f, a metal oxide film 108af to be the semiconductor layer 108a and a metal oxide film 108bf to be the semiconductor layer 108b are stacked. The metal oxide film 108f is provided to be in contact with the top surface and the side surface of the conductive layer 112b, the top surface and the side surface of the insulating layer 110, and the top surface of the conductive layer 112a.

The metal oxide film 108af and the metal oxide film 108bf are each preferably formed by a sputtering method using a metal oxide target. Alternatively, each of the metal oxide film 108af and the metal oxide film 108bf is preferably formed by an ALD method. After the formation of the metal oxide film 108af, the metal oxide film 108bf is preferably formed successively without exposure of the surface of the metal oxide film 108af to the air. When the metal oxide film 108af and the metal oxide film 108bf are successively formed, attachment of impurities derived from the air to the surface of the metal oxide film 108af can be inhibited. Examples of the impurities include water and organic substances. Note that an apparatus used for forming the metal oxide film 108af and an apparatus used for forming the metal oxide film 108bf may be different from each other. Alternatively, the formation method of the metal oxide film 108af and the formation method of the metal oxide film 108bf may be different from each other.

The metal oxide film 108af and the metal oxide film 108bf are each preferably a dense film with as few defects as possible. The metal oxide film 108af and the metal oxide film 108bf are each preferably a highly purified film in which impurities including a hydrogen element are reduced as much as possible. It is particularly preferable to use a metal oxide film having crystallinity as each of the metal oxide film 108af and the metal oxide film 108bf.

In forming the metal oxide film 108af and the metal oxide film 108bf, an oxygen gas is preferably used. In particular, in the case of using an oxygen gas at the time of forming the metal oxide film 108af, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the semiconductor layer 108 in a later step, so that the amount of oxygen vacancy and V_{O}H in the semiconductor layer 108 can be reduced.

In forming the metal oxide film 108af and the metal oxide film 108bf, an oxygen gas and an inert gas (e.g., a helium gas, an argon gas, or a xenon gas) may be mixed. At the time of forming the metal oxide film, the crystallinity of the metal oxide film can be increased and a transistor with higher reliability can be obtained with a higher flow rate ratio of oxygen to the film formation gas or with a higher oxygen partial pressure. On the other hand, when the oxygen flow rate ratio or the oxygen partial pressure is lower, the crystallinity of the metal oxide film is lower and a transistor with high on-state current can be obtained. Note that the oxygen flow rate ratio or the oxygen partial pressure at the time of forming the metal oxide film 108af may be the same as or different from the oxygen flow rate ratio or the oxygen partial pressure at the time of forming the metal oxide film 108bf. With use of different oxygen flow rate ratios or different oxygen partial pressures, the metal oxide film 108af and the metal oxide film 108bf can have different crystallinity.

The oxygen flow rate ratio or the oxygen partial pressure at the time of forming the metal oxide film 108af is preferably lower than the oxygen flow rate ratio or the oxygen partial pressure at the time of forming the metal oxide film 108bf Accordingly, the crystallinity of the metal oxide film 108af to be the semiconductor layer 108a can be lower than the crystallinity of the metal oxide film 108bf to be the semiconductor layer 108b.

In forming the metal oxide film, as the substrate temperature is higher, a denser metal oxide film having higher crystallinity can be formed. On the other hand, as the substrate temperature becomes lower, a metal oxide film having lower crystallinity and higher electric conductivity can be formed. Note that the substrate temperature at the time of forming the metal oxide film 108af and the substrate temperature at the time of forming the metal oxide film 108bf may be the same as or different from each other. With different substrate temperatures, the metal oxide film 108af and the metal oxide film 108bf can have different crystallinity.

The substrate temperatures during the formation of the metal oxide film 108af and the metal oxide film 108bf are each preferably higher than or equal to room temperature and lower than or equal to 250° C., further preferably higher than or equal to room temperature and lower than or equal to 200° C., still further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film is formed with the substrate temperature set at room temperature or without heating the substrate, the crystallinity can be made low.

In the case where the substrate temperatures at the time of forming the metal oxide film 108af and the metal oxide film 108bf are different from each other, the substrate temperature at the time of forming the metal oxide film 108af is preferably lower than the substrate temperature at the time of forming the metal oxide film 108bf.

Here, the metal oxide film 108af and the metal oxide film 108bf can be formed using the same sputtering target; thus, the manufacturing cost can be reduced. Furthermore, when the metal oxide film 108af and the metal oxide film 108bf are formed at the same substrate temperature, the metal oxide film 108af and the metal oxide film 108bf can be formed with high productivity in the same treatment chamber. For example, it is preferable that the metal oxide film 108af and the metal oxide film 108bf be successively formed in the same treatment chamber using the same sputtering target. In that case, the substrate temperature is preferably the same, and the oxygen flow rate ratio or the oxygen partial pressure at the time of forming the metal oxide film 108af is preferably lower than the oxygen flow rate ratio or the oxygen partial pressure at the time of forming the metal oxide film 108bf Thus, the metal oxide film 108af and the metal oxide film 108bf having different crystallinities can be formed with high productivity.

In the case of employing an ALD method, a film formation method such as a thermal ALD method or a plasma enhanced ALD (PEALD) method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the metal oxide film can be formed by an ALD method using a precursor including a constituent metal element and an oxidizer.

For example, in the case where an In—Ga—Zn oxide is formed, three precursors of a precursor including indium, a precursor including gallium, and a precursor including zinc can be used. Alternatively, two precursors of a precursor including indium and a precursor including gallium and zinc may be used.

Examples of the precursor including indium include trimethylindium, tris(2,2,6,6-tetramethyl-3,5-heptanedionato)indium, cyclopentadienylindium, indium(III) chloride, and (3-(dimethylamino)propyl)dimethylindium.

Examples of the precursor including gallium include trimethylgallium, triethylgallium, gallium trichloride, tris(dimethylamido)gallium, gallium(III) acetylacetonate, tris(2,2,6,6-tetramethyl-3,5-heptanedionato)gallium, dimethylchlorogallium, and diethylchlorogallium.

Examples of the precursor including zinc include dimethylzinc, diethylzinc, bis(2,2,6,6-tetramethyl-3,5-heptanedionato)zinc, and zinc chloride.

As examples of the oxidizing agent, ozone, oxygen, and water can be given.

As a method for controlling the composition of a film to be obtained, adjusting one or more of the kinds of source gases, the flow rate ratio of source gases, the flowing time of the source gases, and the order in which the source gases flow is given. By adjusting these, the compositions of the metal oxide film 108af and the metal oxide film 108bf can be made different from each other. Moreover, by adjusting these, a film whose composition is continuously changed can be formed. The compositions of one or both of the metal oxide film 108af and the metal oxide film 108bf may be continuously changed.

For example, a precursor used for forming the metal oxide film 108af preferably has a lower gallium content percentage than a precursor used for forming the metal oxide film 108bf. Alternatively, a precursor that does not include gallium may be used for the formation of the metal oxide film 108af, and a precursor that includes gallium may be used for the formation of the metal oxide film 108bf. Although gallium is given as the element M here, one embodiment of the present invention is not limited thereto. Instead of gallium or in addition to gallium, any one or more of the above elements M may be used.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 108f (specifically, the metal oxide film 108af). For example, heat treatment can be performed at a temperature higher than or equal to 70° C. and lower than or equal to 200° C. in a reduced-pressure atmosphere. Alternatively, plasma treatment may be performed in an atmosphere including oxygen. Alternatively, oxygen may be supplied to the insulating layer 110 by plasma treatment in an atmosphere including an oxidizing gas such as dinitrogen monoxide (N₂O). Performing plasma treatment including a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

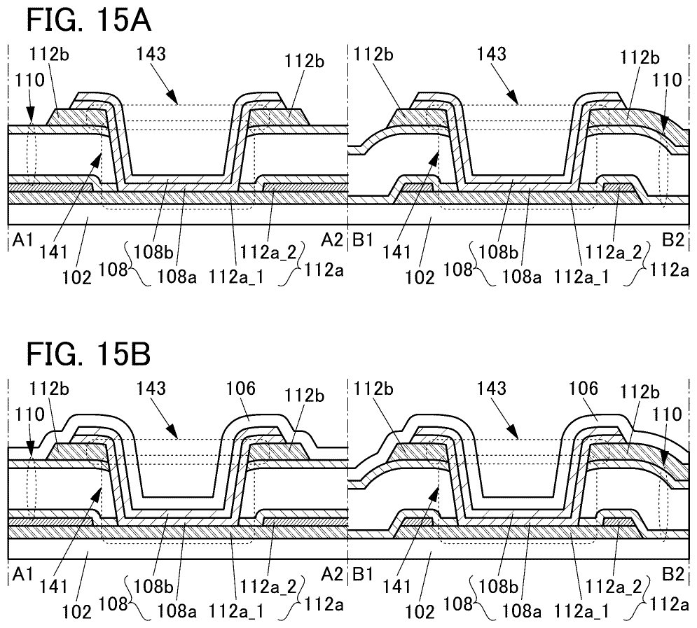

Next, the metal oxide film 108f is processed into an island shape to form the semiconductor layer 108 (FIG. 15A).

For the formation of the semiconductor layer 108, one or both of a wet etching method and a dry etching method can be used; for example, a wet etching method is suitable. At this time, part of the conductive layer 112b in a region not overlapping with the semiconductor layer 108 is etched and thinned in some cases. In a similar manner, part of the insulating layer 110 in a region overlapping with neither the semiconductor layer 108 nor the conductive layer 112b is etched and thinned in some cases. For example, in the insulating layer 110, the insulating layer 110c is removed by etching and the surface of the insulating layer 110b is exposed, in some cases. Note that in etching of the metal oxide film 108f, a reduction in the thickness of the insulating layer 110c can be inhibited when a material having high selectivity is used for the insulating layer 110c.

It is preferable that heat treatment be performed after the metal oxide film 108f is formed or the metal oxide film 108f is processed into the semiconductor layer 108. By the heat treatment, hydrogen or water included in the metal oxide film 108f or the semiconductor layer 108 or adsorbed onto the surface of the metal oxide film 108f or the semiconductor layer 108 can be removed. Furthermore, the film quality of the metal oxide film 108f or the semiconductor layer 108 is improved (e.g., the number of defects is reduced or crystallinity is increased) by the heat treatment in some cases.

Oxygen can be supplied from the insulating layer 110b to the metal oxide film 108f or the semiconductor layer 108 by heat treatment. In this case, it is further preferable that the heat treatment be performed before the semiconductor film 108f is processed into the semiconductor layer 108. The above description can be referred to for the heat treatment; thus, the detailed description thereof is omitted.

Note that the heat treatment is not necessarily performed. The heat treatment in this step may be omitted, and heat treatment performed in a later step may also serve as the heat treatment in this step. In some cases, treatment at a high temperature in a later step (e.g., a film formation step) or the like can serve as the heat treatment in this step.

Then, the insulating layer 106 is formed to cover the semiconductor layer 108, the conductive layer 112b, and the insulating layer 110 (FIG. 15B). For the formation of the insulating layer 106, for example, a PECVD method or an ALD method is suitable.

In the case of using an oxide semiconductor for the insulating layer 108, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, the transistor can have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating layer 106 functioning as the gate insulating layer, the insulating layer including a small number of defects can be obtained. However, the high temperature at the time of forming the insulating layer 106 sometimes allows release of oxygen from the semiconductor layer 108, which increases the amount of oxygen vacancy and V_{O}H in the semiconductor layer 108 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor can have favorable electrical characteristics and high reliability.

Before the formation of the insulating layer 106, the surface of the semiconductor layer 108 may be subjected to plasma treatment. By the plasma treatment, an impurity adsorbed onto the surface of the semiconductor layer 108, such as water, can be reduced. Thus, impurities at the interface between the semiconductor layer 108 and the insulating layer 106 can be reduced, achieving a highly reliable transistor. The plasma treatment is particularly suitable in the case where the surface of the semiconductor layer 108 is exposed to the air after the formation of the semiconductor layer 108 and before the formation of the insulating layer 106. For example, plasma treatment can be performed in an atmosphere including oxygen, ozone, nitrogen, dinitrogen monoxide, argon, or the like. The plasma treatment and the formation of the insulating layer 106 are preferably performed successively without exposure to the air.

Next, the conductive layer 104 is formed over the insulating layer 106 (FIG. 1A and FIG. 1i). A conductive film to be the conductive layer 104 can be favorably formed by a sputtering method, an ALD method, or the like. After a resist mask is formed over the conductive film by a photolithography process, the conductive film is processed, so that the island-shaped conductive layer 104 functioning as a gate electrode can be formed.

Through the above steps, the semiconductor device of one embodiment of the present invention can be manufactured.

This embodiment can be combined with the other embodiments as appropriate.

### Embodiment 3

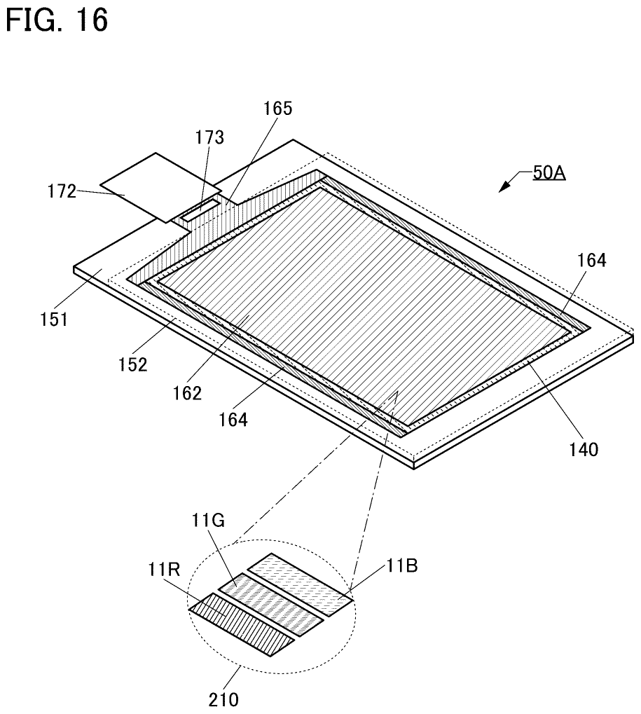

In this embodiment, display devices of embodiments of the present invention are described with reference to FIG. 16 to FIG. 24.

The display device of this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module which is mounted with an integrated circuit (IC) by a chip on glass (COG) method, a chip on film (COF) method, or the like, and the like.

<Display Device 50a>

FIG. 16 is a perspective view of a display device 50A.

In the display device 50A, a substrate 152 and a substrate 151 are bonded to each other. In FIG. 16, the substrate 152 is indicated by a dashed line.

The display device 50A includes a display portion 162, a connection portion 140, a circuit portion 164, a wiring 165, and the like. FIG. 16 illustrates an example where an IC 173 and an FPC 172 are mounted on the display device 50A. Thus, the structure illustrated in FIG. 16 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 16 illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or input to the wiring 165 from the IC 173.

FIG. 16 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The transistor of one embodiment of the present invention can be used for one or both of the display portion 162 and the circuit portion 164 of the display device 50A, for example.

When the transistor of one embodiment of the present invention is used for a pixel circuit of the display device, the area occupied by the pixel circuit can be reduced and the display device can have high resolution, for example. When the transistor of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the transistor of one embodiment of the present invention has favorable electrical characteristics, a display device can have increased reliability by using the transistor.

The display portion 162 of the display device 50A is a region where an image is to be displayed, and includes a plurality of pixels 210 that are periodically arranged. An enlarged view of one pixel 210 is illustrated in FIG. 16.

There is no particular limitation on the arrangement of the pixels in the display device of this embodiment, and a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 16 includes a subpixel 11R that emits red light, a subpixel 11G that emits green light, and a subpixel 11B that emits blue light.

The subpixels 11R, 11G, and 11B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display device using a liquid crystal element, a transmissive display device, a reflective display device, and a transflective display device can be given.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode, and the other electrode functions as a cathode.

In this embodiment, the case where a light-emitting element is used as the display element is mainly described as an example.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

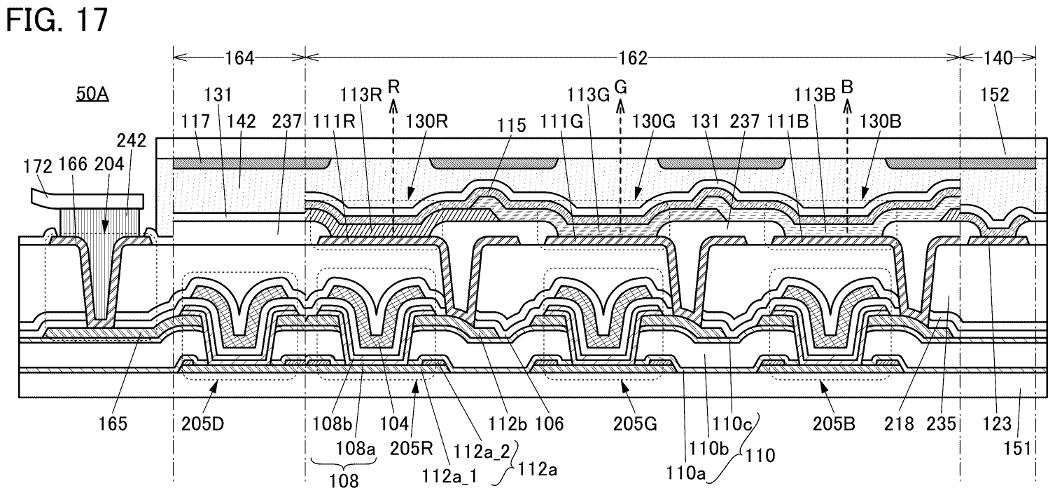

FIG. 17 illustrates an example of cross sections of part of a region including the FPC 172, part of the circuit portion 164, part of the display portion 162, part of the connection portion 140, and part of a region including an end portion of the display device 50A.

The display device 50A illustrated in FIG. 17 includes transistors 205D, 205R, 205G, and 205B, a light-emitting element 130R, a light-emitting element 130G, a light-emitting element 130B, and the like between the substrate 151 and the substrate 152. The light-emitting elements 130R, 130G, and 130B are display elements included in the subpixel 11R that emits red light, the subpixel 11G that emits green light, and the subpixel 11B that emits blue light, respectively.

The display device 50A employs an SBS structure. The SBS structure can optimize materials and structures of light-emitting elements and thus can increase the degree of freedom in selecting materials and structures, so that the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistors 205D, 205R, 205G, and 205B are each formed over the substrate 151. These transistors can be manufactured using the same material through the same process.

This embodiment describes an example where OS transistors are used as the transistors 205D, 205R, 205G, and 205B. The transistor of one embodiment of the present invention can be used as the transistors 205D, 205R, 205G, and 205B. In other words, the display device 50A includes the transistor of one embodiment of the present invention in both the display portion 162 and the circuit portion 164. When the transistor of one embodiment of the present invention is used in the display portion 162, the pixel size can be reduced and high resolution can be achieved. When the transistor of one embodiment of the present invention is used in the circuit portion 164, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate, the insulating layer 106 functioning as a gate insulating layer, the conductive layer 112a and the conductive layer 112b functioning as a source and a drain, the semiconductor layer 108, and the insulating layer 110 (the insulating layers 110a, 110b, and 110c). Here, a plurality of layers obtained by processing the same conductive film are shown with the same hatching pattern. The insulating layer 110 is positioned between the conductive layer 112a and the semiconductor layer 112b. The insulating layer 106 is positioned between the conductive layer 104 and the semiconductor layer 108.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include any one or more of a planar transistor, a staggered transistor, and an inverted staggered transistor. A transistor included in the display device of this embodiment may have either a top-gate structure or a bottom-gate structure. Alternatively, gates may be provided above and below the semiconductor layer where a channel is formed.

A transistor including silicon in its channel formation region (a Si transistor) may be included in the display device of this embodiment.

Examples of silicon include single crystal silicon, polycrystalline silicon, and amorphous silicon. In particular, a transistor including LTPS in its semiconductor layer (hereinafter also referred to as an LTPS transistor) can be used. The LTPS transistor has high field-effect mobility and excellent frequency characteristics.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of an EL element vary, for example. In other words, when the OS transistor operates in the saturation region, the source-drain current hardly changes with a change in the source-drain voltage; hence, the emission luminance of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one of the transistors included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. Accordingly, the insulating layer 218 can function as a barrier film. This structure can effectively inhibit diffusion of impurities into the transistors from the outside and improve the reliability of the display device.

The insulating layer 218 preferably includes one or more inorganic insulating films. Examples of materials that can be used for the inorganic insulating film include an oxide, a nitride, an oxynitride, and a nitride oxide. Specific examples of these materials are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. Accordingly, a depressed portion can be inhibited from being formed in the insulating layer 235 in processing pixel electrodes 111R, 111G, and 111B, for example. Alternatively, a depressed portion may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 17 emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 17 emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 17 emits blue light (B). The EL layer 113B includes a light-emitting layer that emits blue light.

Although the EL layers 113R, 113G, and 113B have the same thickness in FIG. 17, the present invention is not limited thereto. The EL layers 113R, 113G, and 113B may have different thicknesses. For example, the thicknesses of the EL layers 113R, 113G, and 113B are preferably set in accordance with an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can be provided to have a single-layer structure or a stacked-layer structure using one or both of an inorganic insulating material and an organic insulating material. A material that can be used for the insulating layer 218 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The common electrode 115 is a continuous film shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material and the same step as the pixel electrodes 111R, 111G, and 111B.

In the display device of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display device.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 17, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 17; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display device.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of high-luminance light emission. Furthermore, the tandem structure allows the amount of current needed for obtaining the same luminance to be reduced as compared to the case of using a single structure, and thus can improve the reliability. The tandem structure may be referred to as a stack structure.

In the case of using a light-emitting element having a tandem structure in FIG. 17, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting elements 130R, 130G, and 130B. The protective layer 131 and the substrate 152 are bonded to each other with an adhesive layer 142 therebetween. The substrate 152 is provided with a light-blocking layer 117. For example, a solid sealing structure or a hollow sealing structure can be employed to seal the light-emitting elements. In FIG. 17, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is further preferable that the protective layer 131 be provided to extend to the end portion of the display device 50A. Meanwhile, a connection portion 204 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one type of insulating films, semiconductor films, and conductive films can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

As the protective layer 131, an inorganic insulating film including an oxide, a nitride, an oxynitride, or a nitride oxide can be used, for example. Specific examples of these materials are as described above. In particular, the protective layer 131 preferably includes a nitride or a nitride oxide, and further preferably includes a nitride.

An inorganic film containing ITO, In—Zn oxide, Ga—Zn oxide, Al—Zn oxide, IGZO, or the like can be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high property of transmitting visible light. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

A connection portion 204 is provided in a region of the substrate 151 not overlapping with the substrate 152. In the connection portion 204, the wiring 165 is electrically connected to the FPC 172 through the conductive layer 166 and a connection layer 242. An example in which the conductive layer 166 is a single conductive layer obtained by processing the same conductive film as the pixel electrodes 111R, 111G, and 111B is shown. On the top surface of the connection portion 204, the conductive layer 166 is exposed. Thus, the connection portion 204 and the FPC 172 can be electrically connected to each other through the connection layer 242.

The display device 50A has a top-emission structure. Light emitted from the light-emitting element is emitted toward the substrate 152 side. For the substrate 152, a material having a high visible-light-transmitting property is preferably used. The pixel electrodes 111R, 111G, and 111B include a material that reflects visible light, and the counter electrode (the common electrode 115) includes a material that transmits visible light.

The light-blocking layer 117 is preferably provided on the surface of the substrate 152 that faces the substrate 151. The light-blocking layer 117 can be provided between adjacent light-emitting elements, in the connection portion 140, and in the circuit portion 164, for example.

A coloring layer such as a color filter may be provided on the surface of the substrate 152 that faces the substrate 151 or over the protective layer 131. When the color filter is provided so as to overlap with the light-emitting element, the color purity of light emitted from the pixel can be increased.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of damage can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

<Display Device 50b>

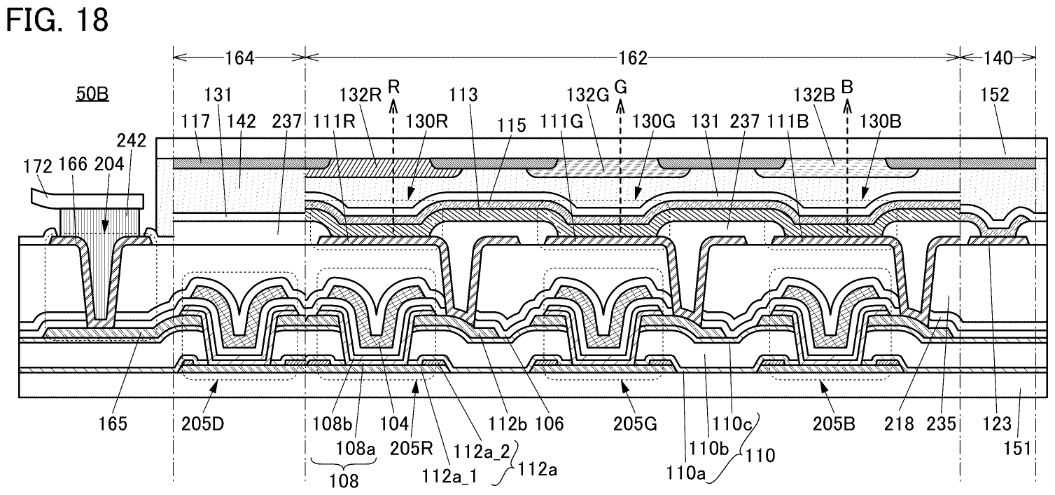

A display device 50B illustrated in FIG. 18 is different from the display device 50A mainly in that an EL layer 113 shared between the light-emitting elements and coloring layers (color filters or the like) are used for the subpixels of different colors. As for the description of the display device below, description of portions similar to those of the above-described display device is omitted in some cases.

The display device 50B illustrated in FIG. 18 includes the transistors 205D, 205R, 205G, and 205B, the light-emitting elements 130R, 130G, and 130B, the coloring layer 132R transmitting red light, the coloring layer 132G transmitting green light, the coloring layer 132B transmitting blue light, and the like between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the structure where the EL layer 113 is provided to be shared between the subpixels of different colors than the structure where the subpixels of different colors are provided with different EL layers.

The light-emitting elements 130R, 130G, and 130B illustrated in FIG. 18 emit white light, for example. When white light emitted from the light-emitting elements 130R, 130G, and 130B passes through the coloring layers 132R, 132G, and 132B, light of desired colors can be obtained.

The light-emitting element that emits white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light having a longer wavelength than blue light, for example. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specifically, examples of applicable structures are as follows: a two-unit tandem structure including a light-emitting unit emitting yellow light and a light-emitting unit emitting blue light; a two-unit tandem structure including a light-emitting unit emitting red light and green light and a light-emitting unit emitting blue light; a three-unit tandem structure in which a light-emitting unit emitting blue light, a light-emitting unit emitting yellow, yellow-green, or green light, and a light-emitting unit emitting blue light are stacked in this order; and a three-unit tandem structure in which a light-emitting unit emitting blue light, a light-emitting unit emitting yellow, yellow-green, or green light and red light, and a light-emitting unit emitting blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting elements 130R, 130G, and 130B illustrated in FIG. 18 emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

<Display Device 50c>

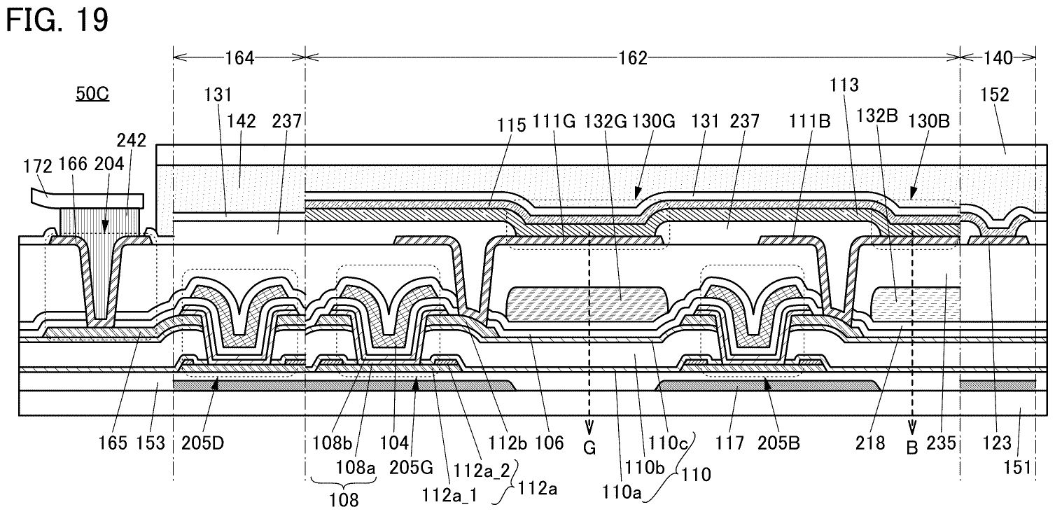

A display device 50C illustrated in FIG. 19 is different from the display device 50B mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 19 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B and the like are provided over the insulating layer 153. In addition, the coloring layer 132R (not illustrated), the coloring layer 132G, and the coloring layer 132B are provided over the insulating layer 218, and the insulating layer 235 is provided over the coloring layer 132R (not illustrated), the coloring layer 132G, and the coloring layer 132B.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111G and 111B. A material reflecting visible light is preferably used for the common electrode 115. In the display device having a bottom-emission structure, a metal or the like having low resistivity can be used for the common electrode 115; thus, a voltage drop due to the resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

<Display Device 50d>

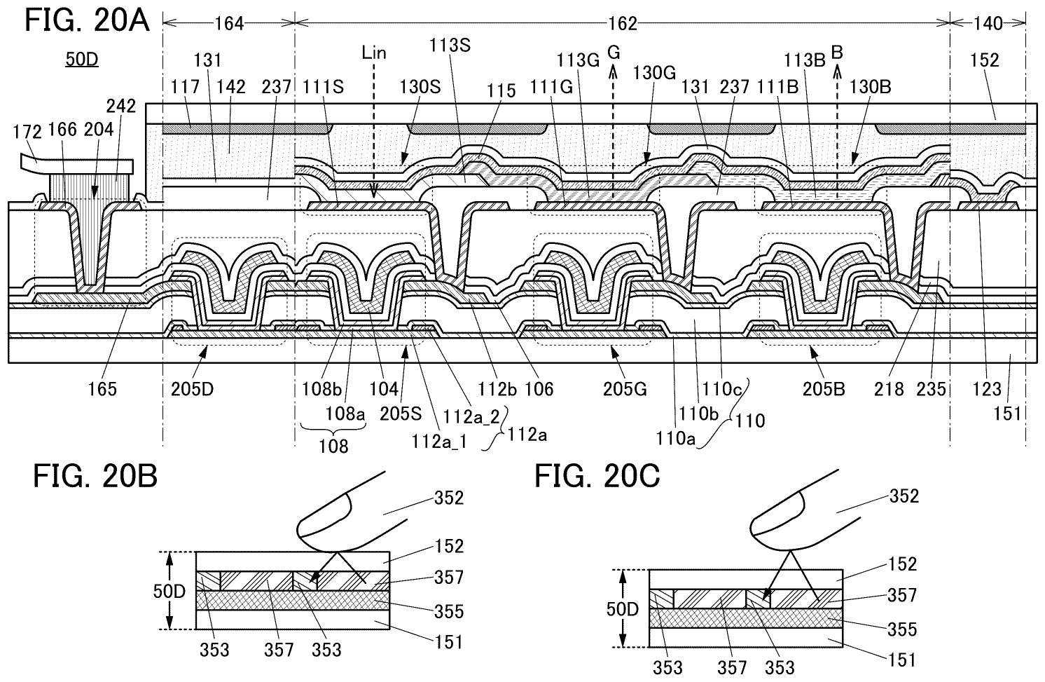

A display device 50D illustrated in FIG. 20A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

In the display device 50D including light-emitting elements and a light-receiving element in each pixel, the pixel has a light-receiving function; thus, the display device can detect a contact or approach of an object while displaying an image. Accordingly, the display portion 162 has one or both of an image capturing function and a sensing function in addition to a function of displaying an image. For example, all the subpixels included in the display device 50D can display an image; alternatively, some of the subpixels can emit light as a light source, some of the rest of the subpixels can detect light, and the other subpixels can display an image.

Accordingly, a light-receiving portion and a light source do not need to be provided separately from the display device 50D; hence, the number of components of an electronic device can be reduced. For example, a biometric authentication device provided in the electronic device, a capacitive touch panel for scroll operation, or the like is not necessarily provided separately. Thus, with the use of the display device 50D, the electronic device can be provided at lower manufacturing costs.

When the light-receiving elements are used as an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect an object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display device 50D.

The pixel electrode 111S is electrically connected to the conductive layer 112b included in a transistor 205S through an opening provided in the insulating layer 106, the insulating layer 218, and the insulating layer 235.

An end portion of the pixel electrode 111S is covered with the insulating layer 237.

The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a substance having a bipolar property (a substance with a high electron-transport property and a high hole-transport property), or the like. Without limitation to the above, the functional layer 113S may further include a layer containing a substance having a high hole-injection property, a hole-blocking material, a substance having a high electron-injection property, an electron-blocking material, or the like. Layers other than the active layer included in the light-receiving element can be formed using a material that can be used for the light-emitting element, for example.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

The display device 50D illustrated in FIG. 20B and FIG. 20C includes, between the substrate 151 and the substrate 152, a layer 353 including a light-receiving element, a circuit layer 355, and a layer 357 including light-emitting elements.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. One or more of a switch, a capacitor, a resistor, a wiring, a terminal, and the like can be provided in the circuit layer 355.

FIG. 20B illustrates an example where the light-receiving element 130S is used as a touch sensor. Light emitted from the light-emitting element in the layer 357 is reflected by a finger 352 that touches the display device 50D as illustrated in FIG. 20B, and the light-receiving element in the layer 353 detects the reflected light. Thus, the touch of the finger 352 on the display device 50D can be detected.

FIG. 20C is an example where the light-receiving element 130S is used as a contactless sensor. Light emitted from the light-emitting element in the layer 357 is reflected by the finger 352 that is approaching (i.e., that is not in contact with) the display device 50D as illustrated in FIG. 20C, and the light-receiving element in the layer 353 detects the reflected light.

<Display Device 50e>

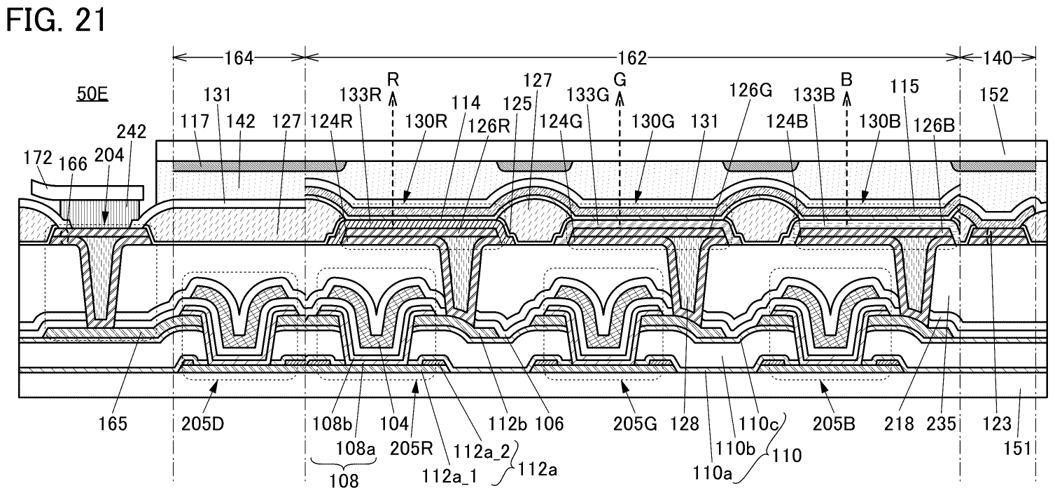

A display device 50E illustrated in FIG. 21 is an example of a display device having an MML (metal maskless) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; thus, the description thereof is omitted.

In FIG. 21, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 21 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 21 emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 21 emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, a leakage current between adjacent light-emitting elements can be inhibited. This can prevent unintended light emission due to crosstalk, so that a display device with extremely high contrast can be obtained.

Although the layers 133R, 133G, and 133B have the same thickness in FIG. 21, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 21 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portion of the pixel electrode has a tapered shape, the layer 133R provided along the side surface of the pixel electrode has a tapered shape. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, top surface and the side surface of the conductive layers 126G are covered with the layer 133G, and the top surface and the side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with the insulating layers 125 and 127. The common layer 114 is provided over the layer 133R, the layer 133G, and the layer 133B and the insulating layers 125 and 127, and the common electrode 115 is provided over the common layer 114. The common layer 114 and the common electrode 115 are each a continuous film shared by a plurality of light-emitting elements.

In FIG. 21, the insulating layer 237 illustrated in FIG. 17 or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 50E. Thus, the distance between adjacent light-emitting elements can be extremely narrowed. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to level difference can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with high planarity and a large radius of curvature.

The insulating layer 125 can be an insulating layer including an inorganic material. For the insulating layer 125, an oxide, a nitride, an oxynitride, or a nitride oxide can be used, for example. Specific examples of these materials are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer or a gettering function, entry of impurities (typically, at least one of water and oxygen) that might diffuse into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used, for example. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved. Furthermore, since the display quality can be increased even when a polarizing plate is not used in the display device, a lightweight and thin display device can be achieved.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### <Display Device 50F>

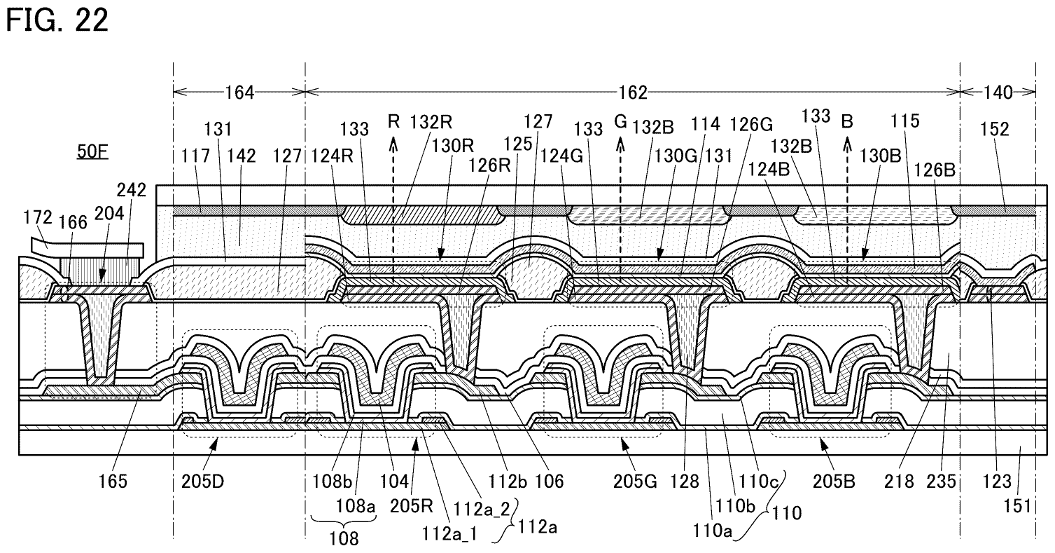

A display device 50F illustrated in FIG. 22 is different from the display device 50E mainly in that the subpixels of different colors are provided with coloring layers (color filters or the like).

In the display device 50F illustrated in FIG. 22, the transistors 205D, 205R, 205G, and 205B, the light-emitting elements 130R, 130G, and 130B, the coloring layer 132R transmitting red light, the coloring layer 132G transmitting green light, the coloring layer 132B transmitting blue light, and the like are provided between the substrate 151 and the substrate 152.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include the layer 133. The three layers 133 are formed using the same process and the same material. The three layers 133 are separated from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

The light-emitting elements 130R, 130G, and 130B illustrated in FIG. 22 emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 22 emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### <Display Device 50G>

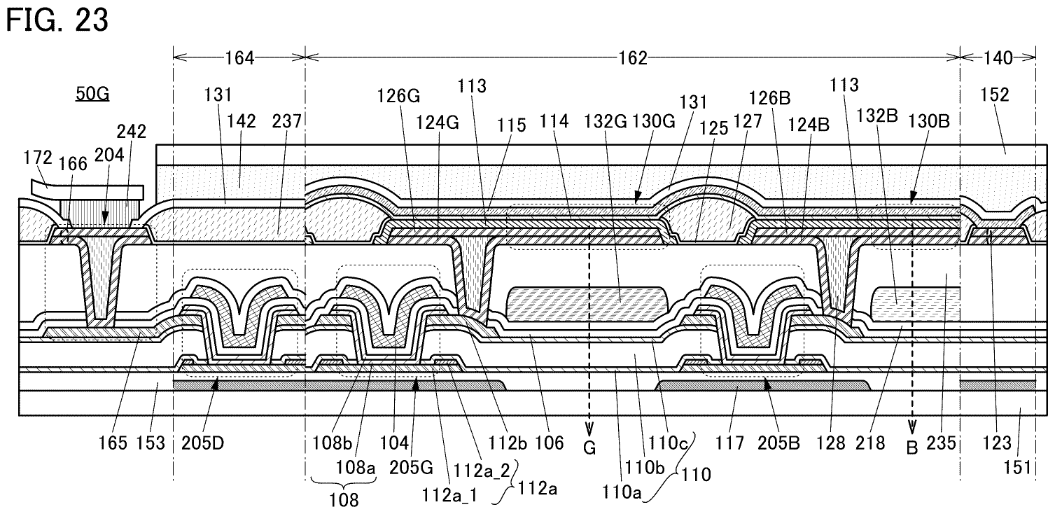

A display device 50G illustrated in FIG. 23 is different from the display device 50F mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 23 illustrates an example where the light-blocking layers 117 are provided over the substrate 151, the insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R (not illustrated), the coloring layer 132G, and the coloring layer 132B are provided over the insulating layer 218, and the insulating layer 235 is provided over the coloring layer 132R (not illustrated), the coloring layer 132G, and the coloring layer 132B.

The light-emitting element 130G overlapping with the coloring layer 132G includes the conductive layer 124G, the conductive layer 126G, the EL layer 113, the common layer 114, and the common electrode 115.

The light-emitting element 130B overlapping with the coloring layer 132B includes the conductive layer 124B, the conductive layer 126B, the EL layer 113, the common layer 114, and the common electrode 115.

A material having a high visible-light-transmitting property is used for each of the conductive layers 124G, 124B, 126G, and 126B. A material reflecting visible light is preferably used for the common electrode 115. In the display device having a bottom-emission structure, a metal or the like having low resistivity can be used for the common electrode 115; thus, a voltage drop due to the resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### <Manufacturing Method Example of Display Device>

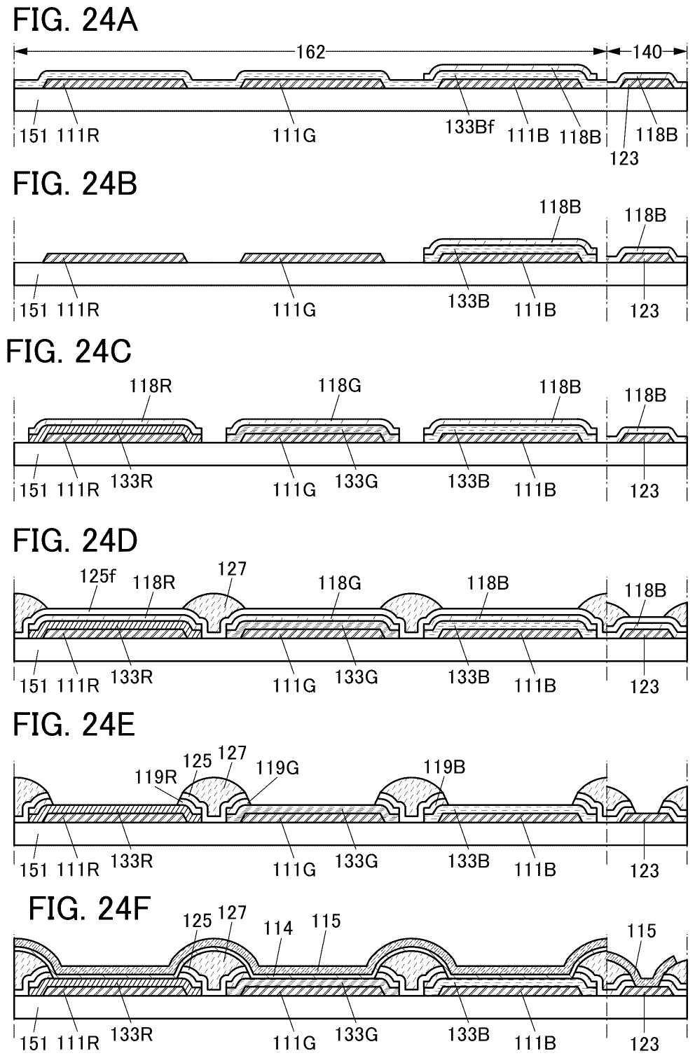

A method for manufacturing a display device having an MML (metal maskless) structure will be described below with reference to FIG. 24. Here, steps of manufacturing light-emitting elements without using a fine metal mask will be described in detail. In FIG. 24, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure method, or a micro-contact printing method).

In the method described below for manufacturing the display device, the island-shaped layer (the layer including the light-emitting layer) is formed not by using a fine metal mask but by forming a light-emitting layer on the entire surface and then processing the light-emitting layer by a photolithography method. Accordingly, a high-resolution display device or a display device with a high aperture ratio, which has been difficult to achieve, can be manufactured. Moreover, light-emitting layers can be formed separately for the respective colors, enabling the display device to perform extremely clear display with high contrast and high display quality. In addition, a sacrificial layer provided over a light-emitting layer can reduce damage to the light-emitting layer in the manufacturing process of the display device, increasing the reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by forming a light-emitting layer and performing processing three times by photolithography.

First, the pixel electrodes 111R, 111G, and 111B and the conductive layer 123 are formed over the substrate 151 provided with the transistors 205R, 205G, and 205B and the like (not illustrated) (FIG. 24A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, one or both of a wet etching method and a dry etching method can be used.

Next, a film 133Bf to be the layer 133B later is formed over the pixel electrodes 111R, 111G, and 111B (FIG. 24A). The film 133Bf (to be the layer 133B later) includes a light-emitting layer that emits blue light.

Note that in an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that island-shaped EL layers be formed in the order of blue, green, and red or in the order of blue, red, and green.

This enables the blue-light-emitting element to keep the favorable state of the interface between the pixel electrode and the EL layer and to be inhibited from having an increased driving voltage. Furthermore, the lifetime of the blue-light-emitting element can be prolonged and the reliability can be increased. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed in the order of red, green, and blue.

As illustrated in FIG. 24A, the film 133Bf is not formed over the conductive layer 123. For example, by using an area mask, the film 133Bf can be formed only in a desired region. Employing a film formation step using an area mask and a processing step using a resist mask enables a light-emitting element to be manufactured by a relatively easy process.

The upper temperature limit of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Thus, the range of choices of the materials and the formation method of the display device can be widened, thereby improving the yield and the reliability.

The upper temperature limit, for example, can be any of the glass transition point, the softening point, the melting point, the thermal decomposition temperature, and the 5% weight loss temperature, preferably the lowest temperature thereof.

The film 133Bf can be formed by an evaporation method, specifically a vacuum evaporation method, for example. Alternatively, the film 133Bf may be formed by a transfer method, a printing method, an inkjet method, a coating method, or the like.

Next, a sacrificial layer 118B is formed over the film 133Bf and the conductive layer 123 (FIG. 24A). A resist mask is formed over a film to be the sacrificial layer 118B by a photolithography process, and then the film is processed, whereby the sacrificial layer 118B can be formed.

The sacrificial layer 118B provided over the film 133Bf can reduce damage to the film 133Bf in the manufacturing process of the display device, increasing the reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can inhibit a variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with the film 133Bf is used.

The sacrificial layer 118B is formed at a temperature lower than the upper temperature limit of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film can have higher density and a higher barrier property as the formation temperature becomes higher. Thus, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the aforementioned wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

The use of a wet etching method can reduce damage to the film 133Bf in processing of the sacrificial layer 118B, as compared with the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more kinds selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with a high affinity for the semiconductor manufacturing process. Alternatively, an oxide or a nitride of the semiconductor material can be used. Alternatively, a non-metal such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. The use of an ALD method is preferable because damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. Here, for the sacrificial layer 118B and the insulating layer 125, the same film-formation condition may be used or different film-formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer most or all of which is to be removed in a later step, and thus is preferably easy to process. Thus, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet film formation method and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 24B).

Accordingly, as illustrated in FIG. 24B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 24C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B, and the sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 600 and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a display device with a high resolution and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 24D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage due to the film formation can be reduced and a film with high coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display device can be manufactured with high productivity.

For example, the insulating film to be the insulating layer 127 is preferably formed by the aforementioned wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays, so that the insulating film is partly exposed to light. Subsequently, the region of the insulating film exposed to light is removed by development. After that, heat treatment (also referred to as post-baking) is performed. Accordingly, the insulating layer 127 illustrated in FIG. 24D can be formed. Note that the shape of the insulating layer 127 is not limited to the shape illustrated in FIG. 24D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 24E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Note that parts of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, providing the insulating layer 127, the insulating layer 125, the sacrificial layer 118B, the sacrificial layer 118G, and the sacrificial layer 118R can inhibit the common layer 114 and the common electrode 115 between the light-emitting elements from having connection defects due to a disconnected portion and an increase in electric resistance due to a locally thinned portion. Thus, the display quality of the display device of one embodiment of the present invention can be improved.

Next, the common layer 114 and the common electrode 115 are formed in this order over the insulating layer 127, the layer 133B, the layer 133G, and the layer 133R (FIG. 24F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film over the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. Accordingly, generation of a leakage current between the subpixels can be inhibited. This can prevent unintended light emission due to crosstalk, so that a display device with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display device of one embodiment of the present invention can have both a higher resolution and higher display quality.

This embodiment can be combined with the other embodiments as appropriate.

### Embodiment 4

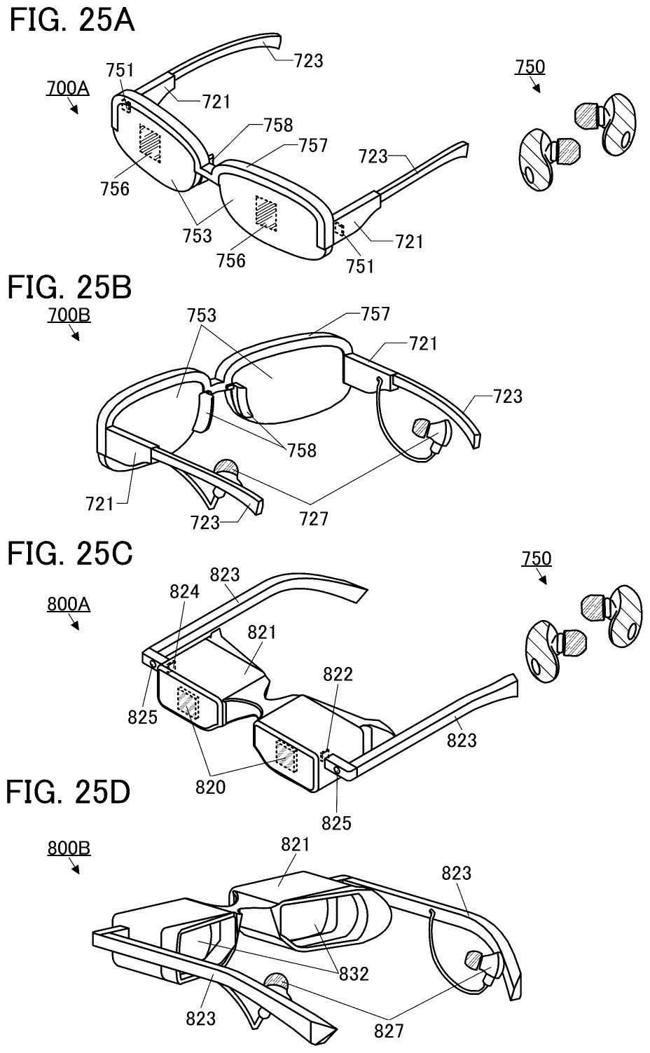

In this embodiment, electronic devices of one embodiment of the present invention will be described with reference to FIG. 25 to FIG. 27.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display device of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 25A to FIG. 25D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 25A and an electronic device 700B illustrated in FIG. 25B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 25C and an electronic device 800B illustrated in FIG. 25D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 25D.

The display device of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of the display portions 820 displays different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 25C and the like illustrate examples where the wearing portion has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 25A has a function of transmitting information to the earphones 750 with the wireless communication function. As another example, the electronic device 800A illustrated in FIG. 25C has a function of transmitting information to the earphones 750 with the wireless communication function.

The electronic device may include an earphone portion. The electronic device 700B illustrated in FIG. 25B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 25D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

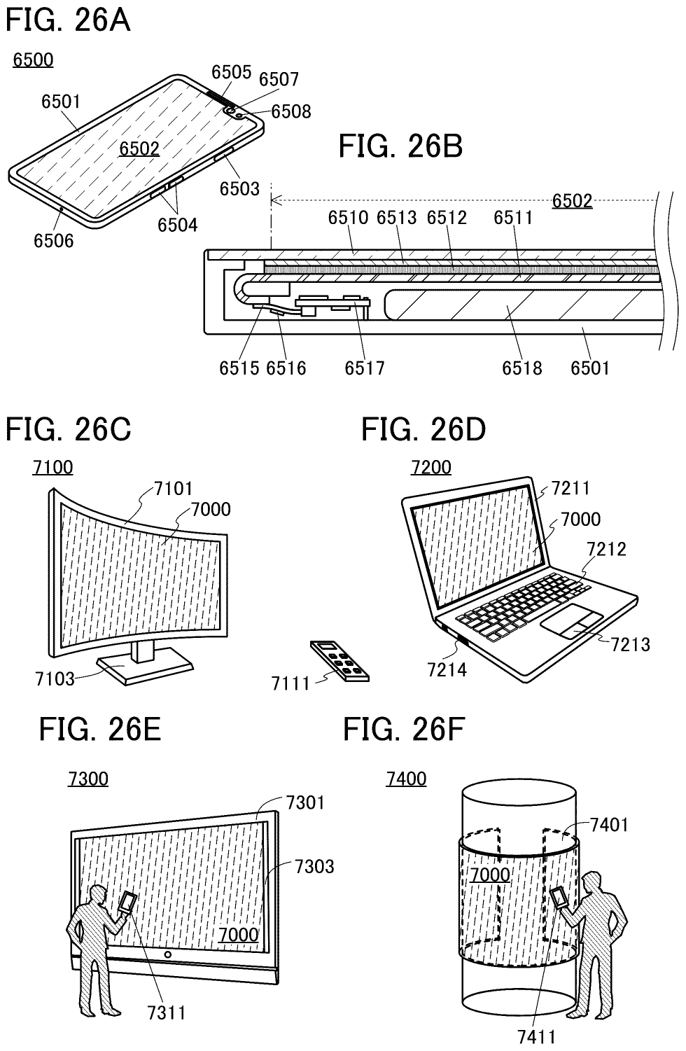

An electronic device 6500 illustrated in FIG. 26A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 26B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in thickness of the electronic device is reduced. Moreover, part of the display panel 6511 is folded back so that a connection portion with the FPC 6515 is provided on the back side of the pixel portion, whereby an electronic device with a narrow bezel can be achieved.

FIG. 26C illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 26C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 26D illustrates an example of a laptop computer. A laptop computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 26E and FIG. 26F illustrate examples of digital signage.

Digital signage 7300 illustrated in FIG. 26E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 26F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 26E and FIG. 26F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 26E and FIG. 26F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

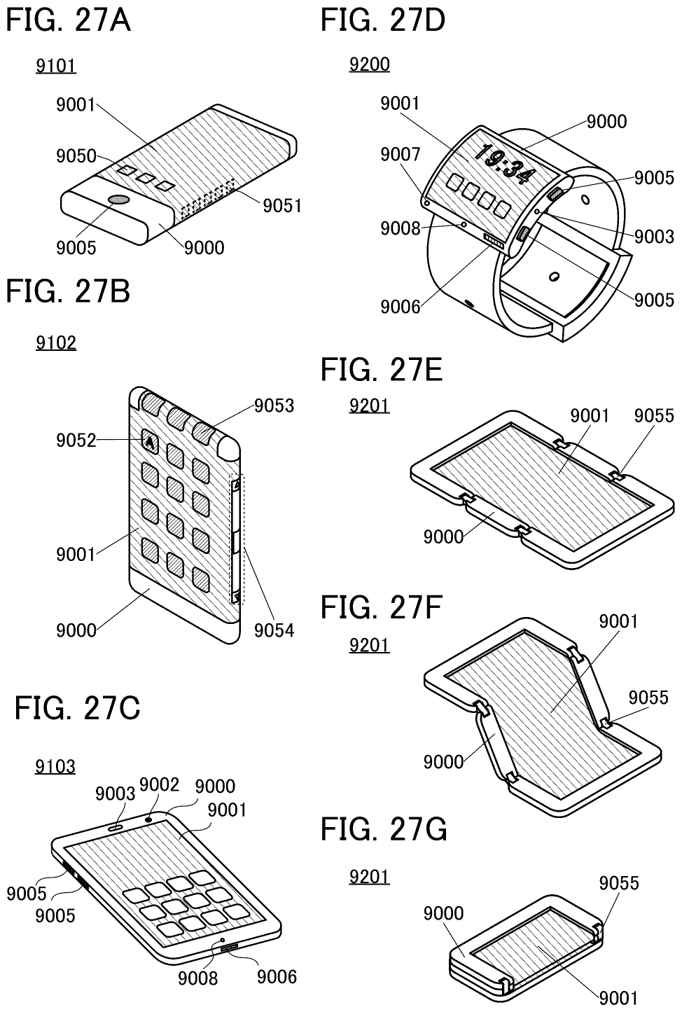

Electronic devices illustrated in FIG. 27A to FIG. 27G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 27A to FIG. 27G.

The electronic devices illustrated in FIG. 27A to FIG. 27G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 27A to FIG. 27G are described in detail below.

FIG. 27A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 27A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 27B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 27D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 27E to FIG. 27G are perspective views illustrating a foldable portable information terminal 9201. FIG. 27E is a perspective view of an opened state of the portable information terminal 9201, FIG. 27G is a perspective view of a folded state thereof, and FIG. 27F is a perspective view of a state in the middle of change from one of FIG. 27E and FIG. 27G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example

In this example, transistors (Sample A to Sample D) of one embodiment of the present invention were fabricated and their electrical characteristics were evaluated.

For the structures of Sample A to Sample D, the description of the transistor 100C illustrated in FIG. 4C can be referred to. For the methods for fabricating Sample A to Sample D, the description in Embodiment 2 can be referred to. Note that the structure illustrated in FIG. 8A and the like was used for the insulating layer 110. Specifically, the insulating layer 110 had a stacked-layer structure of the insulating layer 110d, the insulating layer 110a, the insulating layer 110b, and the insulating layer 110c.

### <Fabrication of Samples>

First, an In—Sn—Si oxide (ITSO) film with a thickness of approximately 100 nm was formed over the substrate 102 by a sputtering method, and then processed to obtain the conductive layer 112a. A glass substrate was used as the substrate 102.

Next, the first insulating film to be the insulating layer 110d, the second insulating film to be the insulating layer 110a, and a third insulating film to be the insulating layer 110b were formed in this order over the substrate 102 and the conductive layer 112a. The first insulating film to the third insulating film were successively formed by a PECVD method.

An approximately 50-nm-thick silicon nitride film was used as the first insulating film. For the formation of the first insulating film, a mixed gas of a silane (SiH₄) gas at a flow rate of 200 sccm, a nitrogen (N₂) gas at a flow rate of 2000 sccm, and an ammonia (NH₃) gas at a flow rate of 2000 sccm was used; the pressure at the time of the formation was 200 Pa; the power supply was 2000 W; and the substrate temperature was 350° C.

As the second insulating film, an approximately 30-nm-thick silicon nitride film was used. For the formation of the second insulating film, a mixed gas of a silane (SiH₄) gas at a flow rate of 200 sccm, a nitrogen (N₂) gas at a flow rate of 2000 sccm, and an ammonia (NH₃) gas at a flow rate of 100 sccm was used; the pressure at the time of the formation was 100 Pa; the power supply was 2000 W; and the substrate temperature was 350° C.

As described above, the ammonia flow rate ratio of the film formation gas used for the formation of the first insulating film to be the insulating layer 110d was higher than the ammonia flow rate ratio of the film formation gas used for the formation of the second insulating film to be the insulating layer 110a. In this manner, the hydrogen content of the insulating layer 110d can be higher than that of the insulating layer 110a.

As the third insulating film, an approximately 300-nm-thick silicon oxynitride film was used. For the formation of the third insulating film, a mixed gas of a silane (SiH₄) gas at a flow rate of 200 sccm and a dinitrogen monoxide (N₂O) gas at a flow rate of 6000 sccm was used; the pressure at the time of the formation was 200 Pa; the power supply was 1200 W; and the substrate temperature was 350° C.

Next, an approximately 20-nm-thick IGZO film was formed as the metal oxide layer 149 over the third insulating film. The IGZO film was formed by a sputtering method using an IGZO sputtering target with an atomic ratio of metal elements of In:Ga:Zn=1:1:1. The oxygen flow rate ratio at the time of the formation was 100%, and the substrate temperature was room temperature.

Next, heat treatment was performed at 350° C. in a dry air (CDA) atmosphere for one hour. An oven apparatus was used for the heat treatment.

Next, the metal oxide layer 149 was removed. The metal oxide layer 149 was removed by a wet etching method.

A fourth insulating film to be the insulating layer 110c was formed over the third insulating film. As the fourth insulating film, an approximately 30-nm-thick silicon nitride film was used. For the formation of the fourth insulating film, a mixed gas of a silane (SiH₄) gas at a flow rate of 200 sccm, a nitrogen (N₂) gas at a flow rate of 2000 sccm, and an ammonia (NH₃) gas at a flow rate of 100 sccm was used; the pressure at the time of the formation was 100 Pa; the power supply was 2000 W; and the substrate temperature was 350° C.

Then, a 100-nm-thick In—Sn—Si oxide (ITSO) film was formed as the conductive film 112bf over the fourth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b having the opening 143, and the first insulating film to the fourth insulating film in a region overlapping with the conductive layer 112a were removed to form the insulating layer 110 having the opening 141. For the removal of the conductive film 112bf, a wet etching method was used. The first insulating film to the fourth insulating film were removed by a dry etching method. The top surface shapes of the opening 141 and the opening 143 were circular.

Subsequently, the metal oxide film 108f was formed to cover the opening 141 and the opening 143. The structure of the metal oxide film 108f differed between the samples.

In Sample A, the metal oxide film 108f had a single-layer structure. An approximately 20-nm-thick IGZO film was formed as the metal oxide film 108f. The IGZO film was formed by a sputtering method using an IGZO sputtering target with an atomic ratio of metal elements of In:Ga:Zn=1:1:1. The oxygen flow rate ratio at the time of the formation was 10%, and the substrate temperature was room temperature.

In Sample B, the metal oxide film 108f had a single-layer structure. An approximately 20-nm-thick IGZO film was formed as the metal oxide film 108f. The IGZO film was formed by a sputtering method using an IGZO sputtering target with an atomic ratio of metal elements of In:Ga:Zn=1:3:2. The oxygen flow rate ratio at the time of the formation was 10%, and the substrate temperature was room temperature.

In Sample C, the metal oxide film 108f had a stacked-layer structure of the metal oxide film 108af and the metal oxide film 108bf over the metal oxide film 108af. As the metal oxide film 108af, an approximately 10-nm-thick IGZO film was formed. The IGZO film was formed by a sputtering method using an IGZO sputtering target with an atomic ratio of metal elements of In:Ga:Zn=1:3:2. The oxygen flow rate ratio at the time of the formation was 10%, and the substrate temperature was room temperature. As the metal oxide film 108bf, an approximately 10-nm-thick IGZO film was formed. The IGZO film was formed by a sputtering method using an IGZO sputtering target with an atomic ratio of metal elements of In:Ga:Zn=1:1:1. The oxygen flow rate ratio at the time of the formation was 10%, and the substrate temperature was room temperature.

In Sample D, the metal oxide film 108f had a stacked-layer structure of the metal oxide film 108af and the metal oxide film 108bf over the metal oxide film 108af. As the metal oxide film 108af, an approximately 10-nm-thick IGZO film was formed. The IGZO film was formed by a sputtering method using an IGZO sputtering target with an atomic ratio of metal elements of In:Ga:Zn=1:1:1. The oxygen flow rate ratio at the time of the formation was 10%, and the substrate temperature was room temperature. As the metal oxide film 108bf, an approximately 10-nm-thick IGZO film was formed. The IGZO film was formed by a sputtering method using an IGZO sputtering target with an atomic ratio of metal elements of In:Ga:Zn=1:3:2. The oxygen flow rate ratio at the time of the formation was 10%, and the substrate temperature was room temperature.

Next, heat treatment was performed at 350° C. in a dry air (CDA) atmosphere for two hours. An oven apparatus was used for the heat treatment.

Then, the metal oxide film 108f was processed to obtain the semiconductor layer 108.

Next, a 30-nm thick silicon oxynitride film was formed as the insulating layer 106 by a plasma CVD method.

Next, a 50-nm-thick titanium film, a 200-nm-thick aluminum film, and a 50-nm-thick titanium film were each formed by a sputtering method. After that, the conductive films were processed to obtain the conductive layer 104.

Thus, a transistor corresponding to the transistor 100C was formed.

Next, a 300-nm-thick silicon nitride oxide film was formed by a plasma CVD method as a protective layer of the transistor.

Subsequently, heat treatment was performed at 300° C. in a dry air (CDA) atmosphere for one hour. An oven apparatus was used for the heat treatment.

Then, an approximately 1.5-μm-thick polyimide film was formed as a planarization layer.

Next, heat treatment was performed at 250° C. in a dry air (CDA) atmosphere for one hour. An oven apparatus was used for the heat treatment.

Through the above steps, Sample A to Sample D were obtained.

<I_{d}-V_{g} Characteristics>

Next, the I_{d}-V_{g} characteristics of the fabricated transistors of Sample A to Sample D were measured.

For measuring the I_{d}-V_{g} characteristics of the transistors, a voltage applied to the gate electrode (hereinafter also referred to as gate voltage (Vg)) was applied from −3 V to +3 V in increments of 0.05 V. Moreover, a voltage applied to the source electrode (hereinafter also referred to as a source voltage (Vₛ)) was 0 V (comm), and a voltage applied to the drain electrode (hereinafter also referred to as a drain voltage (V_{d})) was 0.1 V and 1.2 V.

Here, in each of Sample A to Sample D, a transistor in which the width D143 of the opening 143 was 2.0 μm (channel width of 6.3 μm) was measured. The number of measured transistors was 10 for each sample.

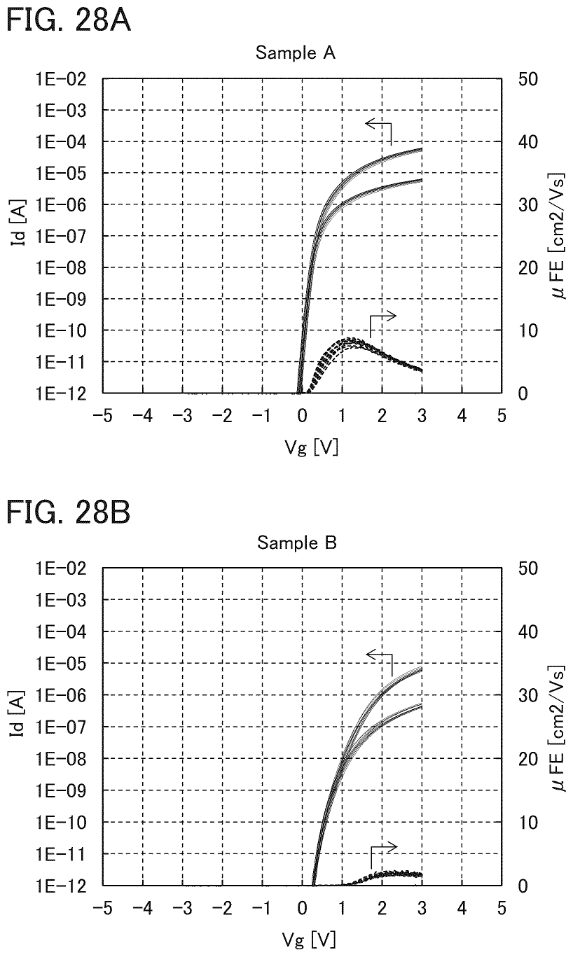

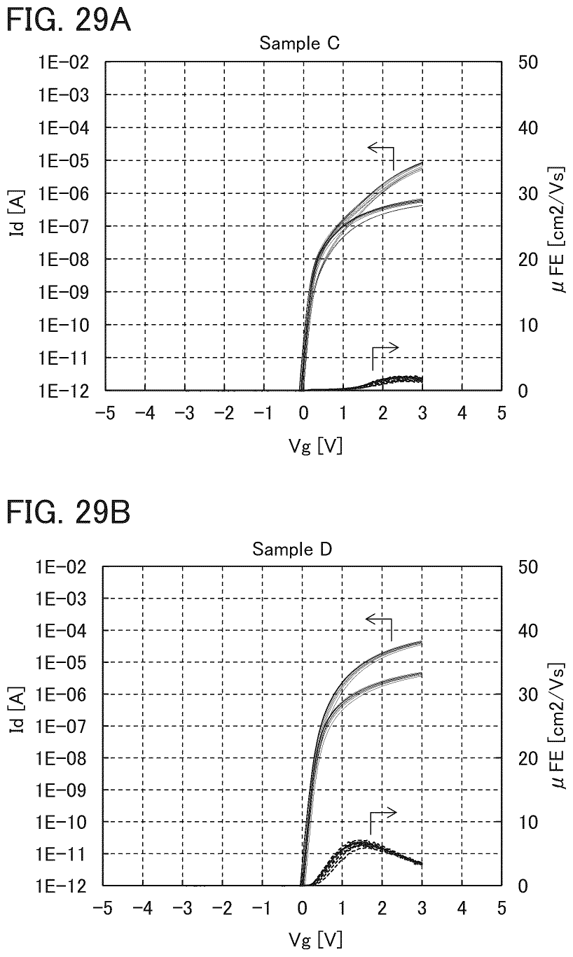

FIG. 28A shows the I_{d}-V_{g} characteristics of Sample A, FIG. 28B shows the I_{d}-V_{g} characteristics of Sample B, FIG. 29A shows the I_{d}-V_{g} characteristics of Sample C, and FIG. 29B shows the I_{d}-V_{g} characteristics of Sample D. In FIG. 28A to FIG. 29B, the horizontal axis represents a gate potential (V_{g}), the left vertical axis represents drain current (I_{d}), and the right vertical axis represents field-effect mobility (μFE) at a drain voltage (V_{d}) of 1.2 V. FIG. 28A to FIG. 29B show superimposed I_{d}-V_{g} characteristics of the 10 transistors.

As shown in FIG. 28A to FIG. 29B, it was found that Sample A to Sample D each exhibited favorable switching characteristics. In addition, Sample A and Sample D were found to have higher on-state current than Sample B and Sample C.

The average value of the shift voltage (Vₛₕ) of the transistors was −0.11 V in Sample A, 0.26 V in Sample B, −0.09 V in Sample C, and −0.03 V in Sample D. Here, Vₛₕ is defined as, in the I_{d}-V_{g} curve of the transistor, V_{g} at which the tangent at a point where the slope of the curve is the steepest intersects the straight line of I_{d}=1 pA. In addition, 36 of Vₛₕ was 0.07 V in Sample A, 0.08 V in Sample B, 0.07 V in Sample C, and 0.08 V in Sample D. Note that a represents a standard deviation. Sample B and Sample D were found to have higher shift voltage (Vₛₕ) than Sample A and Sample C.

The average value of the cutoff current of the transistors was 4.56×10⁻¹¹ A in Sample A, lower than or equal to the lower measurement limit (1.00×10⁻¹² A) in Sample B, 2.19×10⁻¹¹ A in Sample C, and 3.54×10⁻¹² A in Sample D. Sample B and Sample D were found to have lower cutoff current than Sample A and Sample C.

The average value of the subthreshold swing value (S value) of the transistors was 0.07 V in Sample A, 0.13 V in Sample B, 0.07 V in Sample C, and 0.07 V in Sample D. Here, the S value means the amount of change in gate voltage (V_{g}) in the subthreshold region when the drain voltage (V_{d}) keeps constant and the drain current (I_{d}) changes by one order of magnitude.

The average value of the threshold voltage (Vₜₕ) of the transistors was 0.35 V in Sample A, 1.37 V in Sample B, 1.24 V in Sample C, and 0.53 V in Sample D. In addition, 3σ of Vₜₕ was 0.14 V in Sample A, 0.18 V in Sample B, 0.21 V in Sample C, and 0.15 V in Sample D.

From the above results, it was confirmed that a transistor with a small channel length and favorable electrical characteristics can be obtained. It was also found that the transistors of Sample D in which the semiconductor layer 108 had a stacked-layer structure were of normally-off types and had high on-state current.

### REFERENCE NUMERALS

111B: subpixel, 11G: subpixel, 11R: subpixel, 50A: display device, 50B: display device, 50C: display device, 50D: display device, 50E: display device, 50F: display device, 50G: display device, 100A: transistor, 100B: transistor, 100C: transistor, 100D: transistor, 100E: transistor, 100F: transistor, 100G: transistor, 100H: transistor, 100: transistor, 102: substrate, 103: conductive layer, 104: conductive layer, 106a: insulating layer, 106b: insulating layer, 106: insulating layer, 108a: semiconductor layer, 108af: metal oxide film, 108b: semiconductor layer, 108bf: metal oxide film, 108c: semiconductor layer, 108f: metal oxide film, 108: semiconductor layer, 110a: insulating layer, 110af: insulating film, 110b: insulating layer, 110bf: insulating film, 110c: insulating layer, 110cf: insulating film, 110d: insulating layer, 110f: insulating film, 110: insulating layer, 111B: pixel electrode, 111G: pixel electrode, 111R: pixel electrode, 111S: pixel electrode, 112a: conductive layer, 112a_1: conductive layer, 112a_2: conductive layer, 112a_2A: conductive layer, 112B: conductive layer, 112b: conductive layer, 112b_1: conductive layer, 112b_2: conductive layer, 112bf: conductive film, 113B: EL layer, 113G: EL layer, 113R: EL layer, 113S: functional layer, 113: EL layer, 114: common layer, 115: common electrode, 117: light-blocking layer, 118B: sacrificial layer, 118G: sacrificial layer, 118R: sacrificial layer, 119B: sacrificial layer, 119G: sacrificial layer, 123: conductive layer, 124B: conductive layer, 124G: conductive layer, 124R: conductive layer, 125f: insulating film, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133Bf: film, 133G: layer, 133R: layer, 133: layer, 140: connection portion, 141: opening, 142: adhesive layer, 143: opening, 145: opening, 148: opening, 149: metal oxide layer, 151: substrate, 152: substrate, 153: insulating layer, 162: display portion, 164: circuit portion, 165: wiring, 166: conductive layer, 172: FPC, 173: IC, 204: connection portion, 205B: transistor, 205D: transistor, 205G: transistor, 205R: transistor, 205S: transistor, 210: pixel, 218: insulating layer, 235: insulating layer, 237: insulating layer, 242: connection layer, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image-capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first conductive layer;
a first insulating layer comprising a first opening reaching the first conductive layer;
a second conductive layer over the first insulating layer and comprising a second opening overlapping with the first opening;
a first oxide semiconductor layer in contact with a top surface of the first conductive layer, a side surface of the first insulating layer, and a top surface and a side surface of the second conductive layer;
a second oxide semiconductor layer over the first oxide semiconductor layer;
a second insulating layer over the second oxide semiconductor layer; and
a third conductive layer overlapping with the first oxide semiconductor layer and the second oxide semiconductor layer with the second insulating layer therebetween,
wherein each of the first oxide semiconductor layer and the second oxide semiconductor layer comprises a region embedded in the first opening and the second opening, and
wherein a conductivity of the first oxide semiconductor layer is higher than a conductivity of the second oxide semiconductor layer.

2. (canceled)

3. The semiconductor device according to claim 1,
wherein the first oxide semiconductor layer comprises a first metal oxide,
wherein the second oxide semiconductor layer comprises a second metal oxide, and
wherein a band gap of the first metal oxide is smaller than a band gap of the second metal oxide.

4. The semiconductor device according to claim 1,
wherein the first oxide semiconductor layer comprises a first metal oxide,
wherein the second oxide semiconductor layer comprises a second metal oxide,
wherein the first metal oxide comprises indium,
wherein the second metal oxide comprises indium and an element M,
wherein the element M is one or more of gallium, aluminum, and tin, and
wherein a content percentage of the element M in the first metal oxide is lower than a content percentage of the element M in the second metal oxide.

5. (canceled)

6. The semiconductor device according to claim 1, wherein the first conductive layer and the second conductive layer each comprise an oxide conductor.

7. The semiconductor device according to claim 1,
wherein the first insulating layer comprises a third insulating layer, a fourth insulating layer over the third insulating layer, and a fifth insulating layer over the fourth insulating layer,
wherein the fourth insulating layer comprises oxygen, and
wherein the third insulating layer and the fifth insulating layer each comprise nitrogen.

8. The semiconductor device according to claim 1,
wherein the first insulating layer comprises a third insulating layer, a fourth insulating layer over the third insulating layer, a fifth insulating layer over the fourth insulating layer, and a sixth insulating layer over the fifth insulating layer,
wherein the fifth insulating layer comprises oxygen,
wherein the third insulating layer, the fourth insulating layer, and the sixth insulating layer each comprise nitrogen, and
wherein the third insulating layer comprises a region having a higher hydrogen content than the fourth insulating layer.

9. The semiconductor device according to claim 1, comprising:
a fourth conductive layer,
wherein the fourth conductive layer comprises a region in contact with the top surface of the first conductive layer,
wherein the first insulating layer is in contact with the top surface of the first conductive layer and a top surface and a side surface of the fourth conductive layer,
wherein the fourth conductive layer and the third conductive layer overlap with each other with the first insulating layer, the first oxide semiconductor layer, the second oxide semiconductor layer, and the second insulating layer therebetween, and
wherein a conductivity of the fourth conductive layer is higher than a conductivity of the first conductive layer.

10. A semiconductor device comprising a transistor, the transistor comprising:
a first conductive layer as one of a source electrode and a drain electrode of the transistor over a substrate;
a first insulating layer comprising a first opening reaching the first conductive layer;
a second conductive layer as the other of the source electrode and the drain electrode of the transistor over the first insulating layer and comprising a second opening overlapping with the first opening;
a first oxide semiconductor layer in contact with a top surface of the first conductive layer, a side surface of the first insulating layer, and a top surface and a side surface of the second conductive layer;
a second oxide semiconductor layer over the first oxide semiconductor layer;
a second insulating layer over the second oxide semiconductor layer; and
a third conductive layer as a gate electrode of the transistor over the second insulating layer,
wherein each of the first oxide semiconductor layer, the second oxide semiconductor layer, the second insulating layer, and the third conductive layer comprises a region embedded in the first opening and the second opening, and
wherein a crystallinity of the first oxide semiconductor layer is lower than a crystallinity of the second oxide semiconductor layer.
